(19) United States
(12) Patent Application Publication
(10) Pub. No.: US 2026/0353897 A1
(43) Pub. Date: Nov. 5, 2026

(54) DISPLAY DEVICE

(71) Applicant: PanelSemi Corporation, New Taipei City (TW)

(72) Inventor: Rung-Nan LU, New Taipei City (TW)

(21) Appl. No.: 19/663,657

(22) Filed: Apr. 30, 2026

Related U.S. Application Data
(60) Provisional application No. 63/799,951, filed on May 5, 2025.

(51) Int. Cl. H10H 29/855; H10F 55/00; H10H 20/855; H10H 29/24

(52) U.S. Cl. CPC H10H 29/855; H10F 55/00; H10H 20/855; H10H 29/24

(57) ABSTRACT

A display device includes a display layer, a textured layer, and plural light-guiding passage units. The display layer includes plural pixel units, each pixel unit includes one or more pixels, and each pixel includes one or more light-emitting elements. The textured layer is stacked above the display layer, and has a first surface and a second surface. The second surface corresponds to and connects with the display layer. Each light-guiding passage unit includes one or more light-guiding passage structures penetrating through the textured layer. The light-guiding passage units respectively correspond to the pixel units. Each light-guiding passage structure includes a passage communicating between the first and second surfaces. Each light-guiding passage unit's light-guiding passage structure is arranged along a vertical direction perpendicular to the display layer, aligned with one or ones of the pixels of each pixel unit.

### CROSS REFERENCE TO RELATED APPLICATIONS

This Non-provisional application claims priority to U.S. provisional patent application with Ser. No. 63/799,951 filed on May 5, 2025. This and all other extrinsic materials discussed herein are incorporated by reference in their entirety.

### BACKGROUND

### Technology Field

The disclosure relates to an electronic device, and more particularly to a display device with capabilities of environmentally integrated display information.

### Description of Related Art

With the advancement of display technology, people's application needs for display devices are no longer limited to traditional flat screens. In various settings such as building interior walls, decorative columns, art installations, car cabins, or aircraft interiors, there is a desire to perfectly integrate display functionality with environmental decoration. Traditional display panels exhibit obvious black or dark gray appearances when turned off, which limits design flexibility. To address this issue, the industry has developed technology that covers display panels with decorative layers, allowing display areas to naturally harmonize with surrounding environments, such as wood grain decorative materials, when turned off. However, current market solutions still face numerous technical challenges; for example, poor optical coupling efficiency between the decorative layer and the display panel leads to significant reduction in display brightness and tends to cause blurred or distorted display content. Furthermore, the thickness and structure of the decorative layer also affect the overall resolution performance of the display, limiting its practicality in various application scenarios.

### SUMMARY

One aspect of this disclosure is to provide one or more exemplary embodiments of a display device and manufacturing method thereof, to illustrate the display device that takes into account both the integration of the textured layer and the clarity of display content.

Disclosed herein is a display device including a display layer, a textured layer, and a plurality of light-guiding passage units. The display layer includes a plurality of pixel units, each pixel unit includes one or more pixels, and each pixel includes one or more light-emitting elements. The textured layer is stacked above the display layer, wherein the textured layer has a first surface and a second surface disposed opposite to each other, and the second surface corresponds to and connects with the display layer. Each light-guiding passage unit includes one or more light-guiding passage structures penetrating through the textured layer. The light-guiding passage units respectively correspond to the pixel units. Each light-guiding passage structure includes a passage communicating between the first and second surfaces of the textured layer, and a light-guide material arranged in the passage. Each light-guiding passage unit's one or ones of the light-guiding passage structures is arranged along a vertical direction perpendicular to the display layer, aligned with one or ones of the pixels of each pixel unit. At least a portion of the light emitted from the light-emitting elements couples with the light-guiding passage units and emits from the first surface of the textured layer.

Disclosed herein is a manufacturing method of the display device, including preparing a display layer, stacking a textured layer above the display layer, laser-forming a plurality of passages in the textured layer, and arranging a light-guide material in each passage. The display layer includes a plurality of pixel units, each pixel unit includes one or more pixels, and each pixel includes one or more light-emitting elements. The textured layer is stacked above the display layer, wherein the textured layer has a first surface and a second surface disposed opposite to each other, and the second surface corresponds to and connects with the display layer. The passages communicate between the first and second surfaces of the textured layer, and one or more of the passages are aligned with one or more of the pixels in one of the pixel units. A light-guide material is arranged in each passage. At least a portion of the light emitted from the light-emitting elements couples with the passages.

In one embodiment, the textured layer includes a leather texture, a wood texture, or a fabric texture, or a combination including any thereof.

In one embodiment, the passages are formed by laser processing.

In one embodiment, a first opening of one of the passages at the first surface is larger than a second opening thereof at the second surface.

In one embodiment, one of the light-guide materials defines an optical diffusion surface corresponding to the first surface.

In one embodiment, the optical diffusion surface is roughened.

In one embodiment, one of the light-guide materials fills a corresponding one of the passages.

In one embodiment, the one or more light-emitting elements is(are) micro LED(s) or mini LED(s).

In one embodiment, as each of the light-guide passage units is a single light-guide passage structure and each of the pixel units is a single pixel, a light-guide passage pitch is defined between adjacent two of the light-guide passage units. The light-guide passage pitch is a distance from the light-guide passage structure of one of the adjacent two light-guide passage units to the light-guide passage structure of the other one of the adjacent two light-guide passage units, and at least portions of the light-guide passage pitches are equal.

In one embodiment, as each of the light-guide passage units has multiple light-guide passage structures and each of the pixel units has multiple pixels, at least portions of the light-guide passage structures of each of the light-guide passage units respectively correspond to at least portions of the pixels of each of the pixel units, a light-guide passage pitch is defined between adjacent two of the light-guide passage units, from the light-guide passage structure, which is arranged in the vertical direction perpendicular to the display layer, of one of the adjacent two light-guide passage units to a corresponding one of the light-guide passage structures, which is arranged in the vertical direction perpendicular to the display layer, of the other one of the adjacent two light-guide passage units, and at least portions of the light-guide passage pitches are equal.

In one embodiment, as each of the light-guide passage units has multiple light-guide passage structures, and each of the pixel units has multiple pixels, at least portions of the light-guide passage structures of each of the light-guide passage units respectively correspond to at least portions of the pixels of each of the pixel units, one of the light-guide passage structures of each of the light-guide passage units is arranged in an oblique direction, and an angle defined between the oblique direction and the vertical direction is not greater than 90 degrees.

In one embodiment, a first light-guide passage pitch is defined between adjacent two of the light-guide passage units, from the light-guide passage structure, which is arranged in the vertical direction, of one of the adjacent two light-guide passage units to a corresponding one of the light-guide passage structures, which is arranged in the vertical direction, of the other one of the adjacent two light-guide passage units; wherein at least portions of the first light-guide passage pitches are equal.

In one embodiment, a second light-guide passage pitch is defined between adjacent two of the light-guide passage units, from the light-guide passage structure, which is arranged in the oblique direction, of one of the adjacent two light-guide passage units to a corresponding one of the light-guide passage structures, which is arranged in the oblique direction, of the other one of the adjacent two light-guide passage units; wherein at least portions of the second light-guide passage pitches are equal.

In one embodiment, in each of the pixel units, one of the pixels aligned with the light-guide passage structure arranged in the oblique direction and one of the pixels aligned with the light-guide passage structure arranged in the vertical direction are arranged in a staggered configuration in a planar direction of the display layer.

In one embodiment, in each of the light-guide passage units, the light-guide passage structures are free of interference with one another.

In one embodiment, as each of the pixel units has multiple pixels, in each of the pixel units, at least portions of the pixels are identical.

In one embodiment, the one or ones of the light-guide passage structures of each of the light-guide passage units define an opening facing the display layer, wherein a measured area of the opening projected on the display layer in the vertical direction is not smaller than a pixel area of a corresponding one of the pixels.

In one embodiment, the one or ones of the light-guide passage structures of each of the light-guide passage units define an opening facing the display layer, wherein a measured area of the opening projected on the display layer in the vertical direction fully covers a pixel area of a corresponding one of the pixels.

In one embodiment, one or ones of the pixel units include(s) a light sensor, which detects a reflected light reflected from an object and backward to the light sensor.

In one embodiment, the display device further includes an adhesive layer structure; wherein the display layer is connected to the textured layer through the adhesive layer structure.

In one embodiment, the passages penetrate through the textured layer and the adhesive layer structure, along at least portions of the passages, where the adhesive layer structure and the textured layer conjuncts presents a smooth transition.

In one embodiment, a refractive index of the light-guide material is greater than a refractive index of the adhesive layer structure.

In one embodiment, the refractive index of the light-guide material is greater than a refractive index of the textured layer.

In one embodiment, the adhesive layer structure includes one adhesive layer or a plurality of stacked adhesive layers.

In one embodiment, as the adhesive layer structure includes multiple adhesive layers, a first refractive index of one of two adhesive layers and a second refractive index of another one of the two adhesive layers are smaller than a third refractive index of an adhesive layer sandwiched between the two adhesive layers, and one of the adhesive layers having the first refractive index is adjacent to the textured layer.

In one embodiment, the display device further includes a light-transmitting layer arranged between the display layer and the textured layer; wherein the light-transmitting layer is away from the first surface of the textured layer.

In one embodiment, the light-transmitting layer is adjacent to one or ones of the light-emitting elements.

In one embodiment, the light-transmitting layer includes silicon dioxide or silicon nitride.

In one embodiment, the light-transmitting layer presents a continuous surface.

In one embodiment, the light-transmitting layer includes a plurality of light-transmitting units respectively corresponding to the pixel units.

In one embodiment, the light-transmitting layer includes a plurality of light-transmitting units respectively corresponding to the pixels.

In one embodiment, the light-transmitting layer defines a non-light-transmitting region outside the light-transmitting units.

In one embodiment, the light-transmitting layer has a thickness not greater than 5 μm.

In one embodiment, the thickness of the light-transmitting layer is not greater than 1 μm.

In one embodiment, the textured layer is opaque.

In one embodiment, the textured layer defines a transmittance, and under a condition where a light wavelength is not less than 380 nanometers and not greater than 750 nanometers, the transmittance is below 5%.

In one embodiment, the light-guide passage units collectively define a total opening area, wherein relative to a display area of the display device, a ratio of the total opening area is less than 20%.

In one embodiment, the display device further includes a plurality of light-concentrating elements disposed above the pixels and respectively corresponding to the pixels.

In one embodiment, the reflected light is emitted from the first surface of the textured layer and reflected back from the object.

In one embodiment, the reflected light and the emitted light share the same

### LIGHT-GUIDE PASSAGE STRUCTURE.

In one embodiment, the display device further comprises a plurality of auxiliary light-guide passage structures, each aligned with the light sensor of the pixel unit.

In one embodiment, the passages of the auxiliary light-guide passage structures partially interfere with the passages of the light-guide passage structures; wherein, corresponding to the first surface, an optical diffusion surface of the light-guide material of the light-guide passage structure and an optical diffusion surface of the light-guide material of the auxiliary light-guide passage structure are at least partially overlapped.

In one embodiment, the passages of the auxiliary light-guide passage structures are free of interference with the passages of the light-guide passage structures.

In one embodiment, in one of the pixel units, the light sensor unit aligned with the auxiliary light-guide passage structure and the light-emitting element(s) aligned with the light-guide passage structure are arranged in a staggered configuration in a planar direction of the display layer.

In one embodiment, between two pixel units, the emitted light from the light-emitting element(s) of one of the pixel units, after reflection, forms at least part of the reflected light transmitted to the light sensor of another pixel unit.

In one embodiment, between two pixel units, the light emission timing of the light-emitting element(s) of one of the pixel units is offset from the light emission timing of the light-emitting element(s) of another pixel unit.

In one embodiment, between two pixel units, the light emission timing of the light-emitting element(s) of one of the pixel units at least partially overlaps with the detection timing of the light sensor of another pixel unit.

In one embodiment, within the same pixel unit, the light emission timing of the light-emitting element(s) is offset from the detection timing of the light sensor.

In one embodiment, the textured layer is formed by printing.

In one embodiment, the step of arranging the light-guide material further includes forming an optical diffusion surface on the light-guide material in one or ones of the passages corresponding to the first surface of the textured layer.

In one embodiment, the optical diffusion surface is formed by roughening.

In one embodiment, in the step of arranging the light-guide material, at least portions of the light-guide materials fill corresponding ones of the passages.

In one embodiment, the step of laser-drilling at least part of the passages includes implementing laser processing toward the textured layer in a vertical direction perpendicular to the display layer.

In one embodiment, the step of laser-drilling at least part of the passages includes implementing laser processing toward the textured layer in an oblique direction of the display layer; wherein an angle is defined between the oblique direction and the vertical direction and is not greater than 90 degrees.

In one embodiment, a first light-guide passage pitch is defined between two of the passages, wherein the first light-guide passage pitch is distancing from the passage implemented in the vertical direction aligned with one of the pixel units to the passage implemented in the vertical direction aligned with another one of the pixel units; wherein at least portions of the first light-guide passage pitches are equal.

In one embodiment, a second light-guide passage pitch is defined between two of the passages, wherein the second light-guide passage pitch is distancing from the passage implemented in the oblique direction aligned with one of the pixel units to the passage implemented in the oblique direction aligned with another one of the pixel units; wherein at least portions of the second light-guide passage pitches are equal.

In one embodiment, in each of the pixel units, one of the pixels aligned with the oblique direction and one of the pixels aligned with the vertical direction are arranged in a staggered configuration in a planar direction of the display layer.

In one embodiment, the passages are free of interference with one another.

In one embodiment, each of the pixel units has multiple pixels, and at least portions of the pixels are identical.

In one embodiment, each of the passages defines an opening facing the display layer, wherein a measured area of the opening projected in the vertical direction is not smaller than a pixel area of a corresponding one of the pixels.

In one embodiment, each of the passages defines an opening facing the display layer, wherein a measured area of the opening projected in the vertical direction fully covers a pixel area of a corresponding one of the pixels.

In one embodiment, the step of providing the display layer further includes arranging a light sensor in each of the pixel units.

In one embodiment, the step of stacking the textured layer above the display layer further includes arranging an adhesive layer structure between the display layer and the textured layer for bonding the display layer and the textured layer.

In one embodiment, in the step of laser-drilling the passages, the passages penetrate through the textured layer and the adhesive layer structure, along at least portions of the passages, where the adhesive layer structure and the textured layer conjunct presents a smooth transition.

In one embodiment, before the step of laser-forming the passages, the manufacturing method further includes arranging a light-transmitting layer between the display layer and the textured layer; wherein the light-transmitting layer is away from the first surface of the textured layer.

In one embodiment, the light-transmitting layer includes a plurality of light-transmitting units; and before the step of laser-forming the passages, the manufacturing method further includes arranging the light-transmitting units respectively corresponding to the pixel units.

In one embodiment, the light-transmitting layer includes a plurality of light-transmitting units; before the step of laser-forming the passages, the manufacturing method further includes arranging the light-transmitting units respectively corresponding to the pixels.

In one embodiment, in or before the step of laser-forming the passages, the manufacturing method further includes lighting up the light-emitting elements as alignment marks.

In one embodiment, the manufacturing method further includes, before the step of stacking the textured layer, arranging a plurality of light-concentrating elements above the pixels and respectively corresponding to the pixels.

In one embodiment, the steps are implemented in this order.

The foregoing is merely illustrative and not intended to limit the disclosure. In addition to the illustrative embodiments, examples, and features described above, other embodiments, examples, and features of the disclosure can be clearly understood by referring to the drawings and the following detailed description.

### BRIEF DESCRIPTION OF THE DRAWINGS

The disclosure will become more fully understood from the detailed description and accompanying drawings, which are given for illustration only, and thus are not limitative of the present disclosure, and wherein:

FIGS. 1A to 1B and FIGS. 2A to 2C are schematic diagrams showing a display device according to an embodiment of this disclosure;

FIGS. 1C, 1D and 2D are sectional views of the display devices according to different embodiments of this disclosure;

FIGS. 3A to 3F, FIGS. 4A to 4F, FIGS. 5A to 5G, and FIGS. 6A to 6B are schematic diagrams showing the display devices according to different embodiments of this disclosure;

FIGS. 7A to 7F are schematic diagrams showing the manufacturing procedure of a display device according to an embodiment of this disclosure; and

FIGS. 8A to 8N are flowcharts of manufacturing methods of the display device according to different embodiments of this disclosure.

### DETAILED DESCRIPTION OF THE DISCLOSURE

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

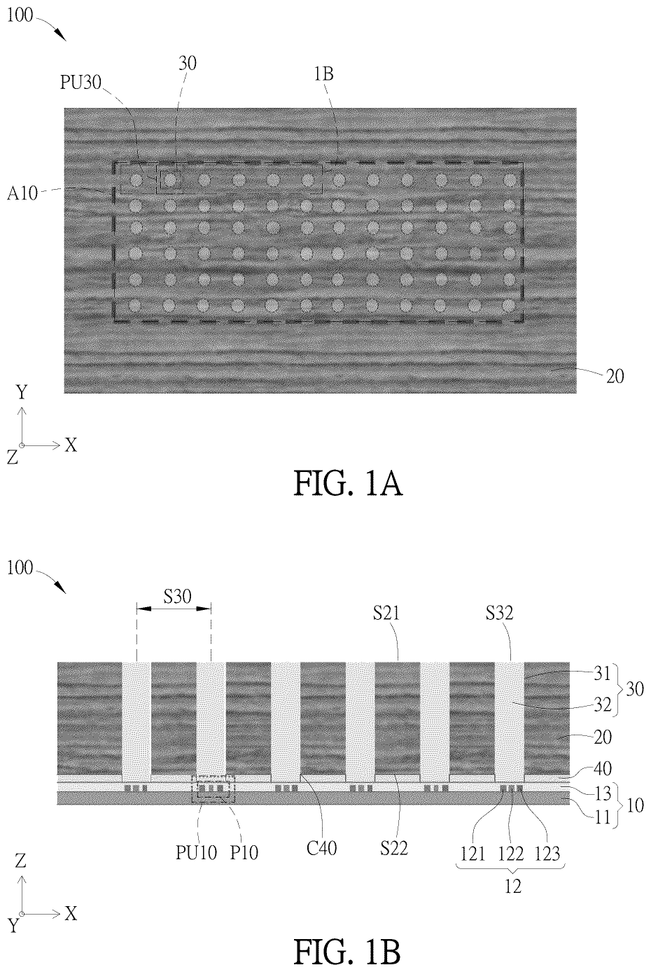

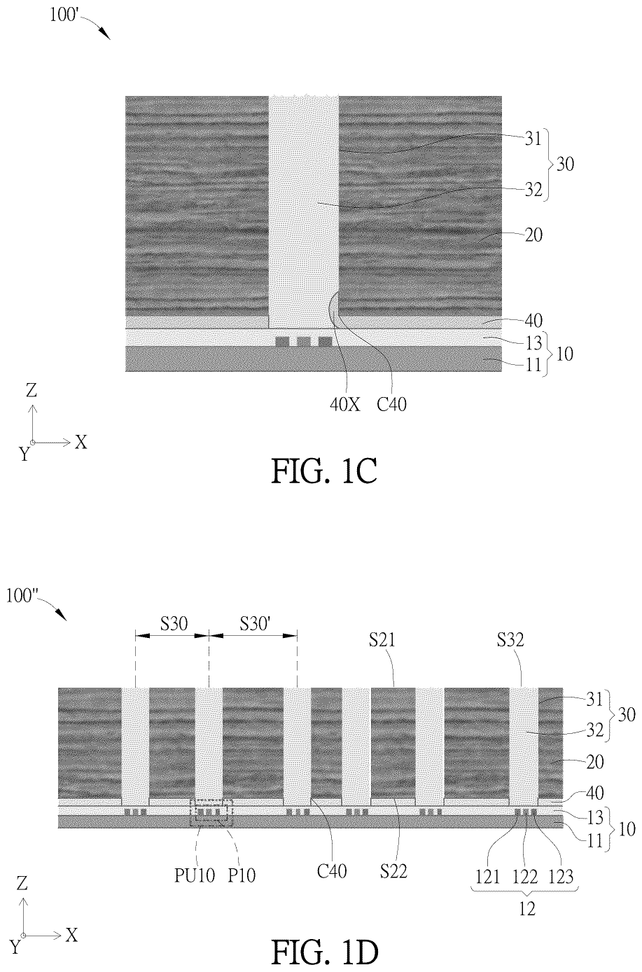

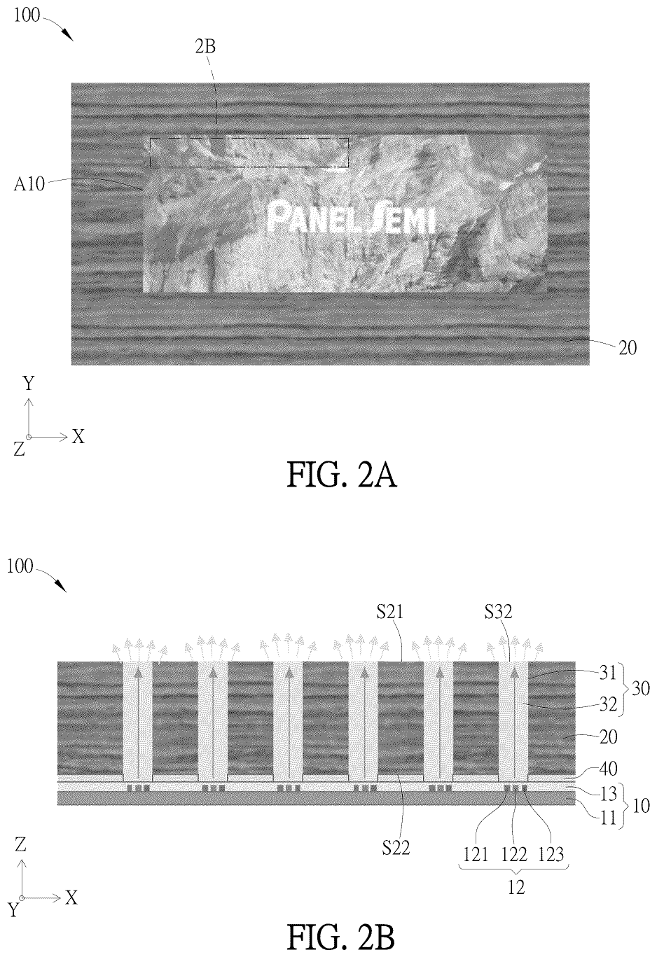

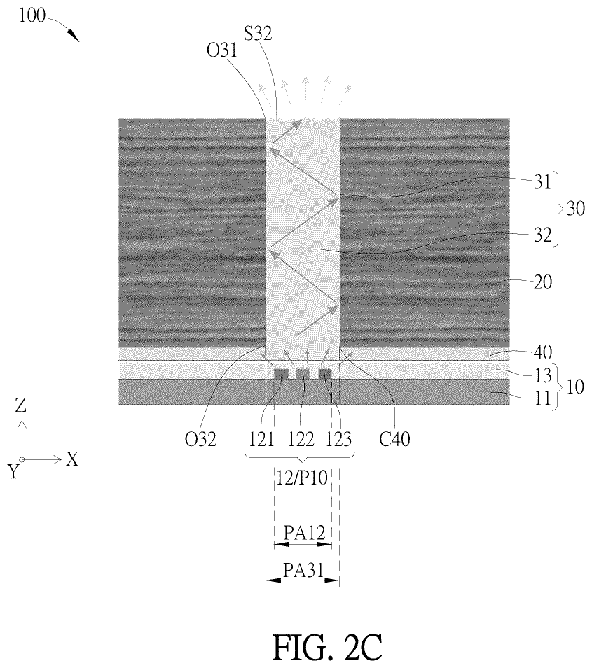

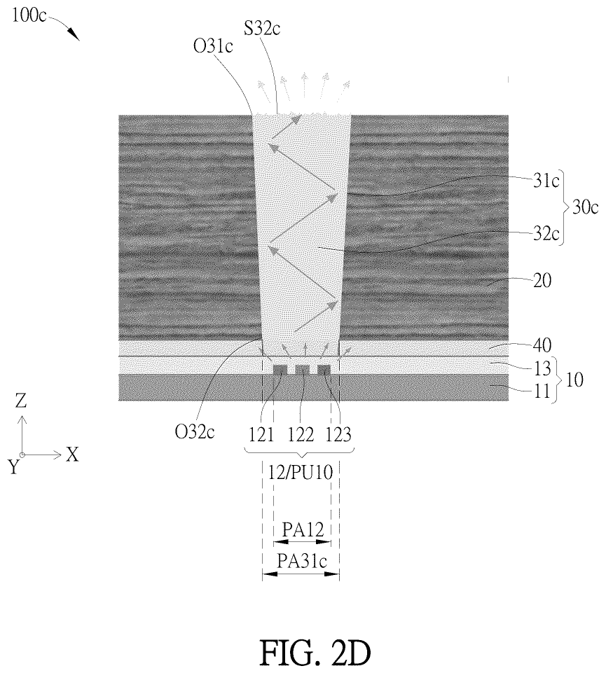

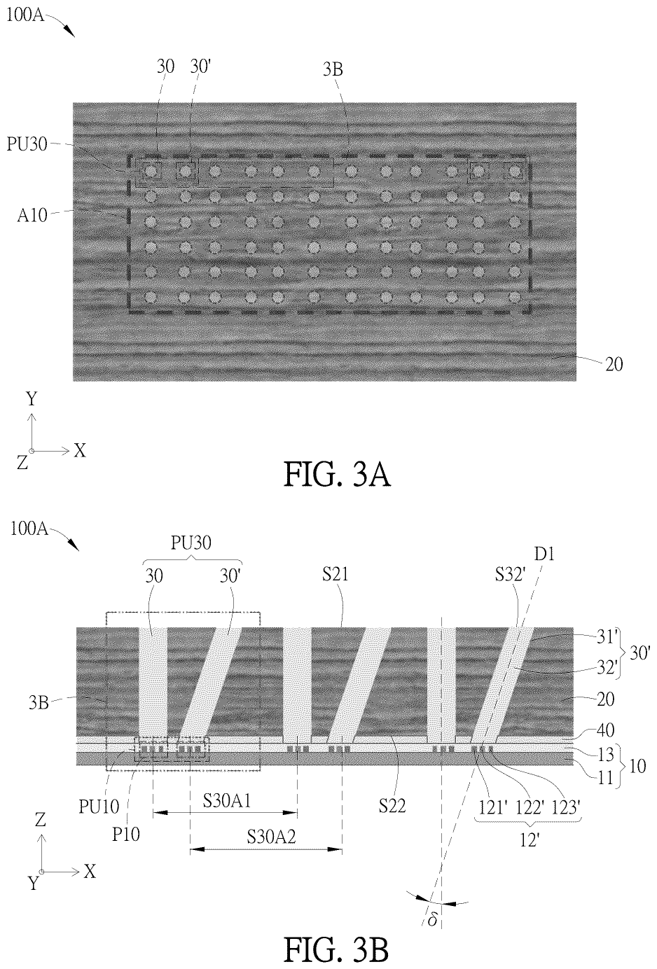

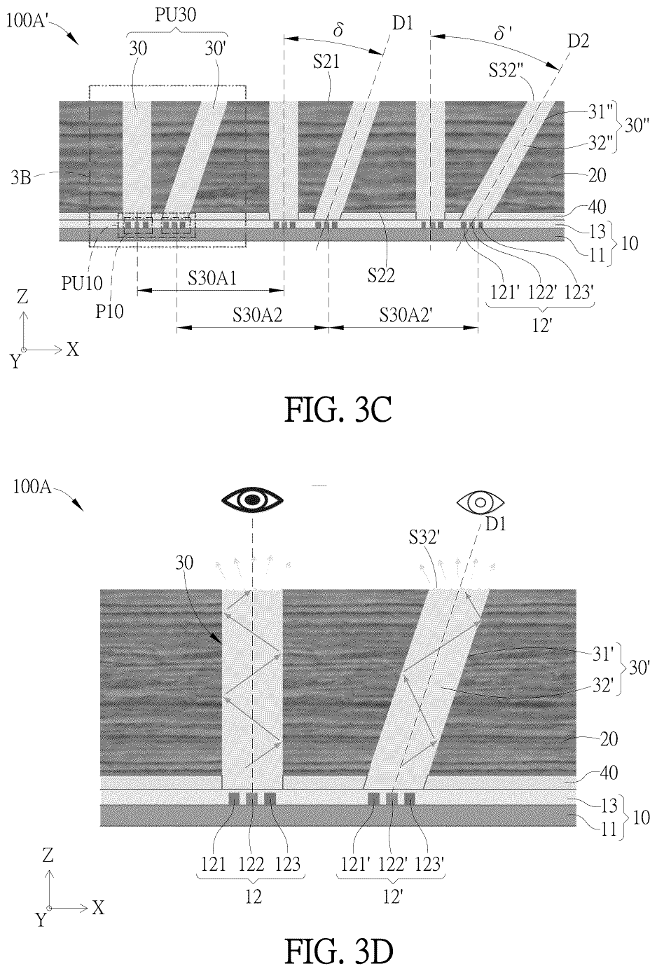

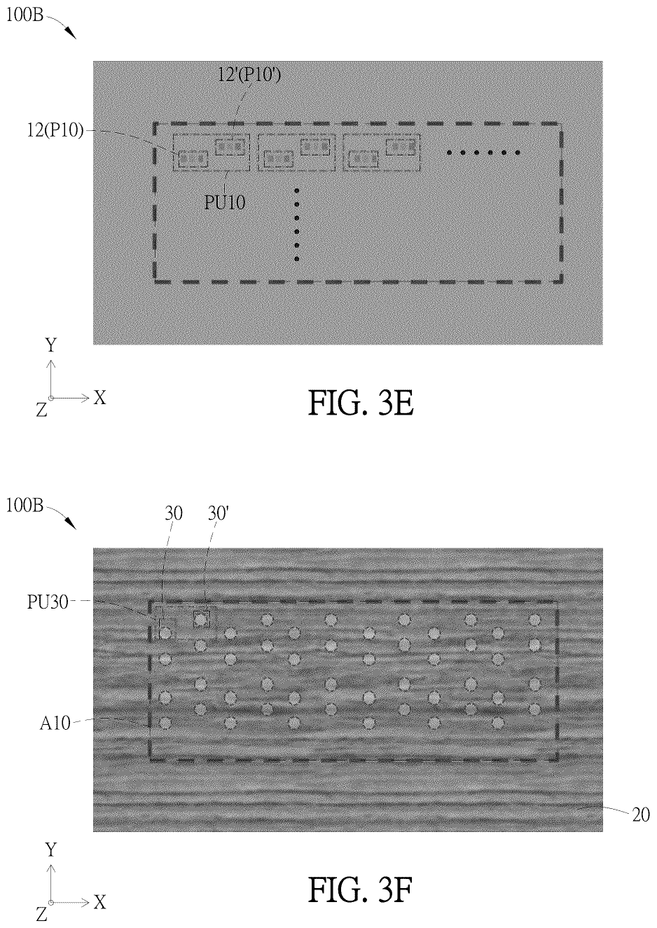

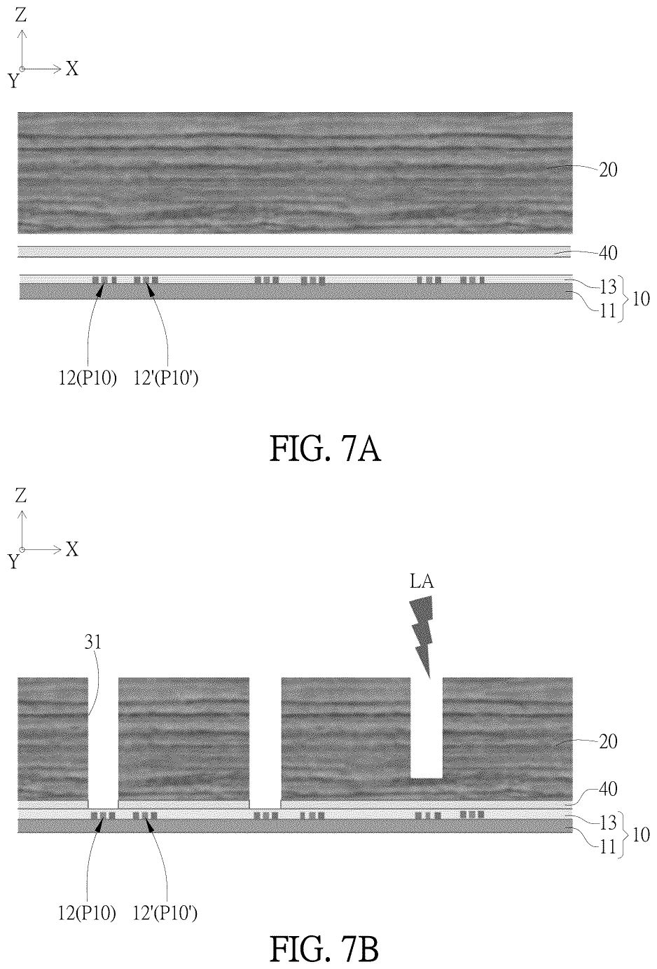

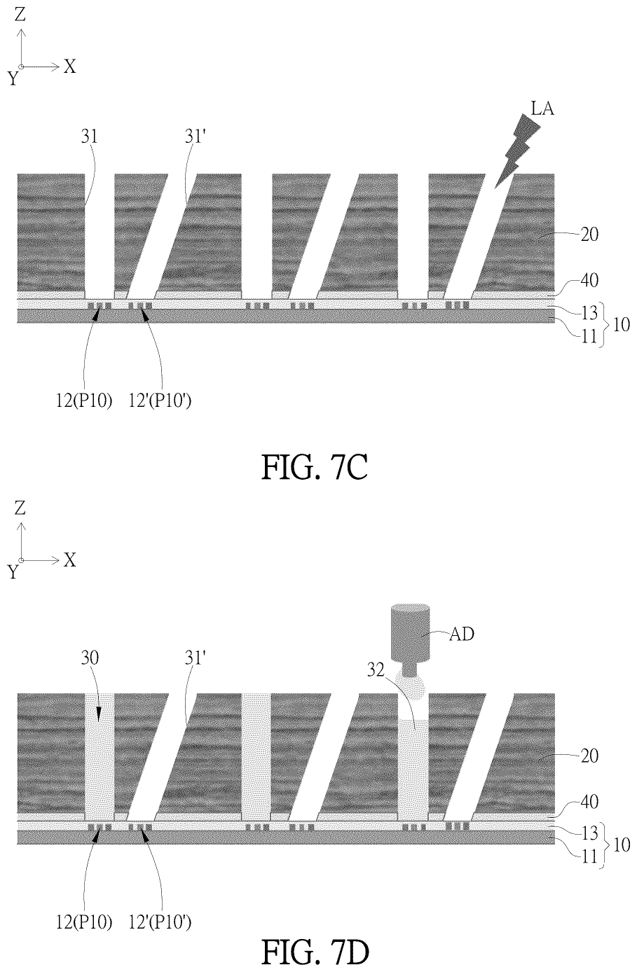

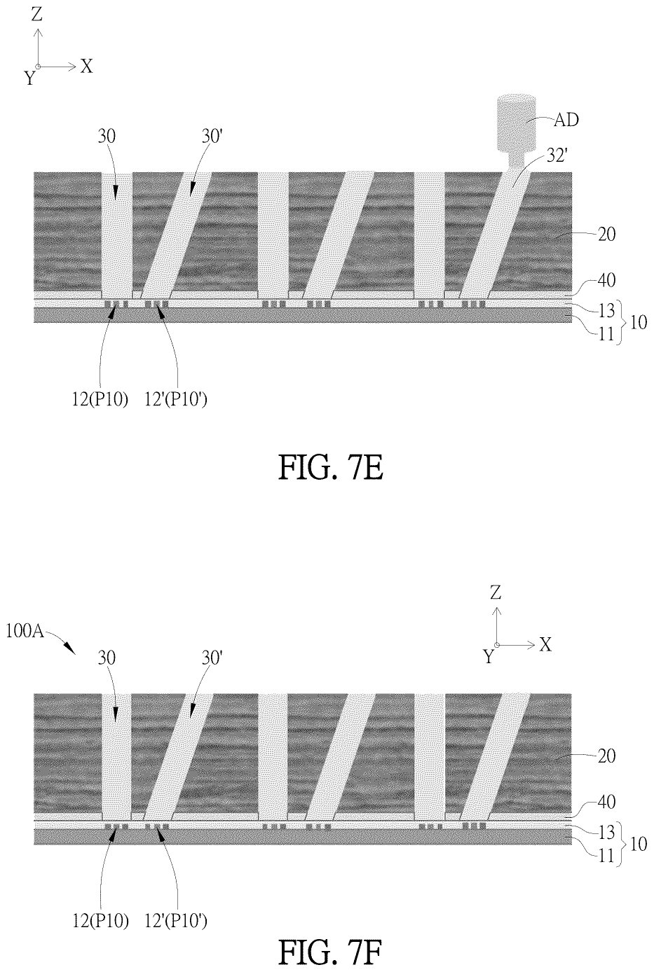

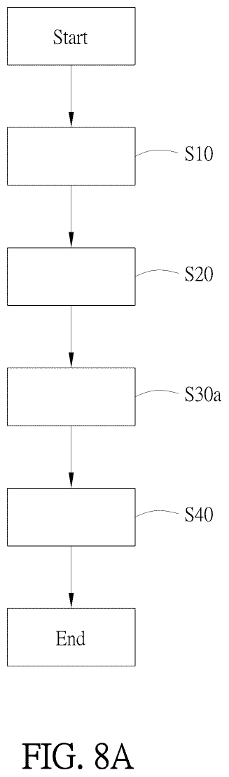

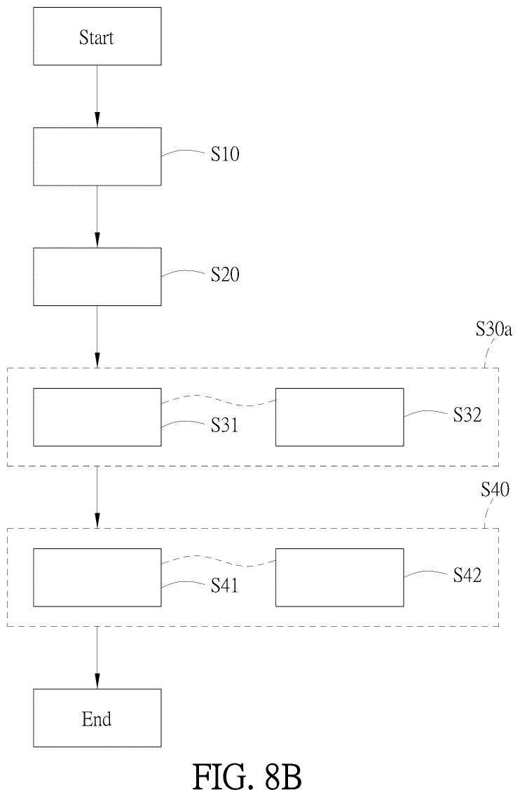

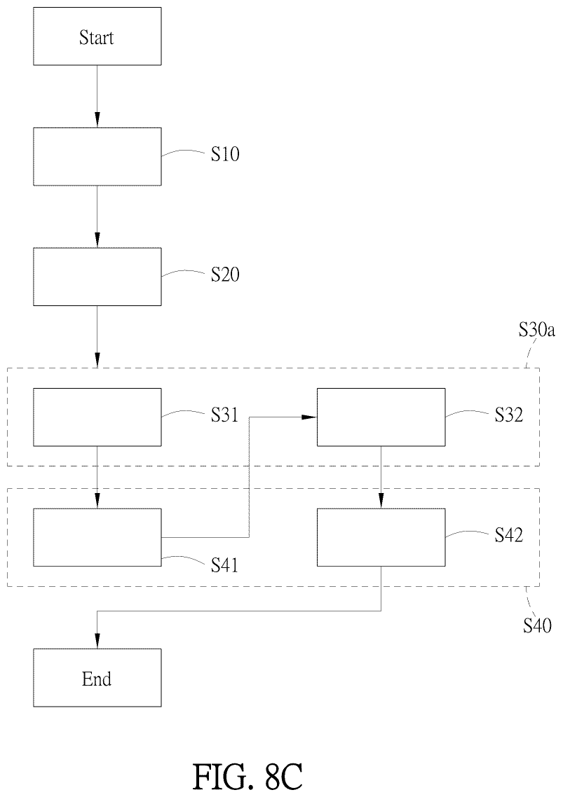

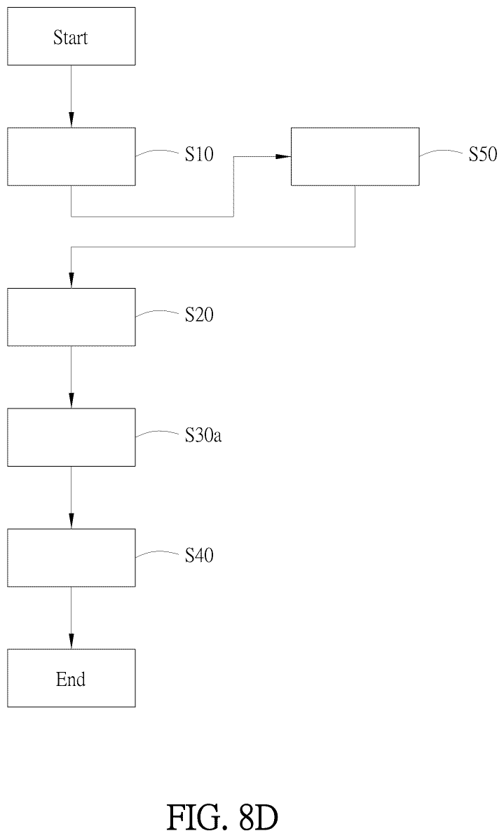

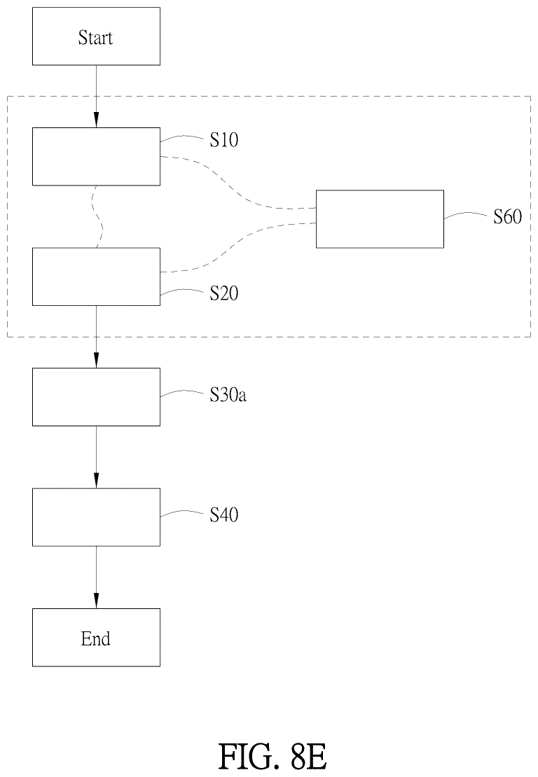

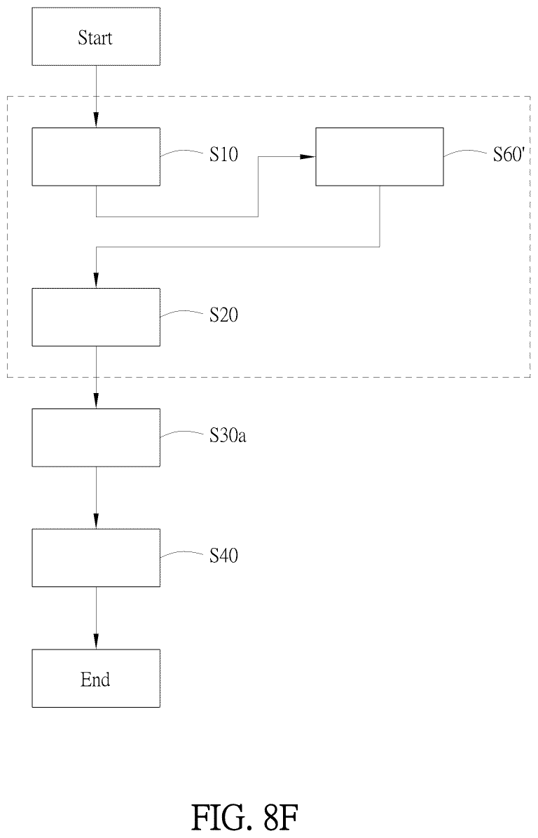

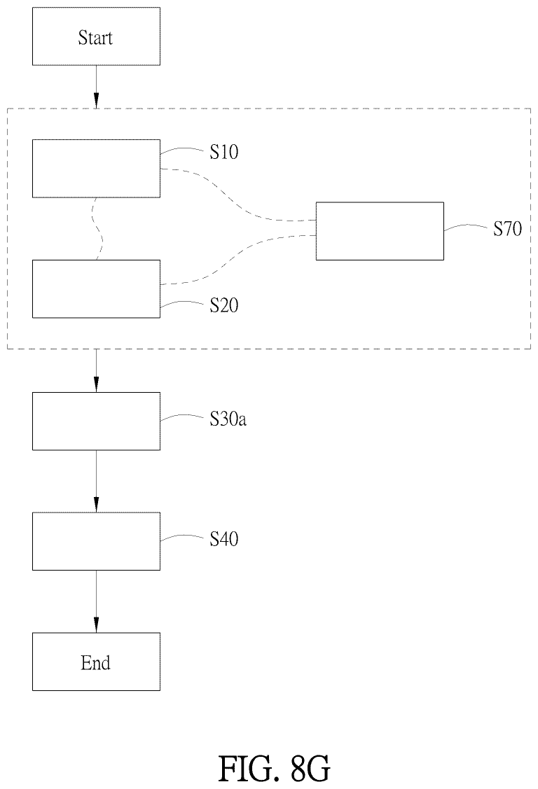

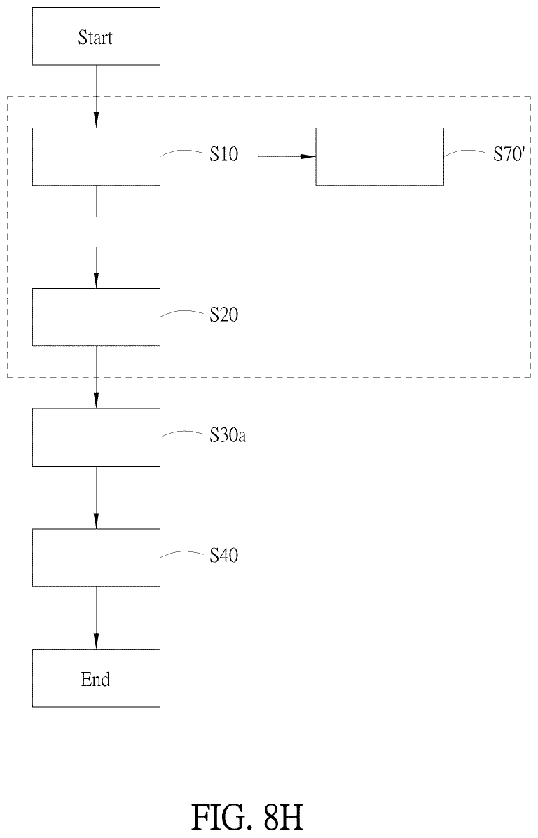

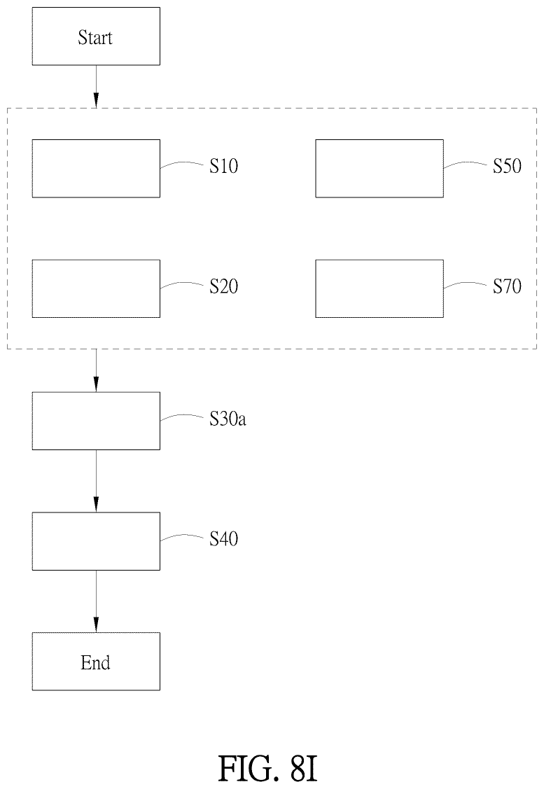

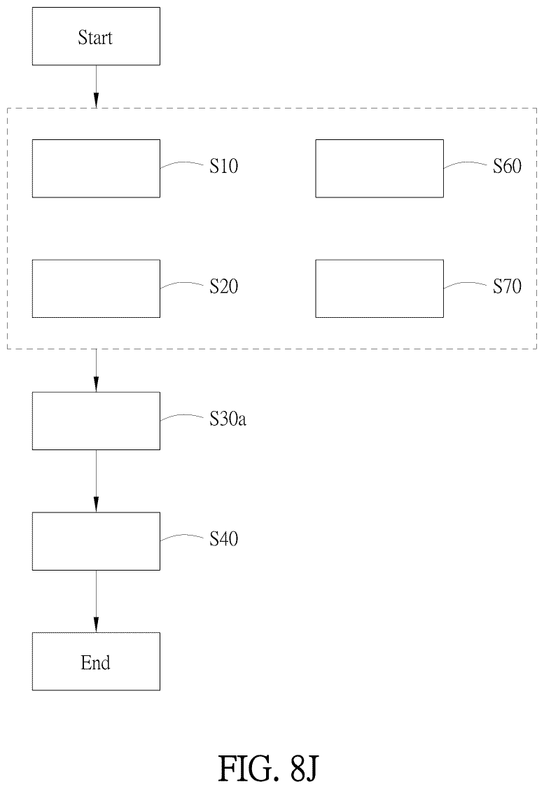

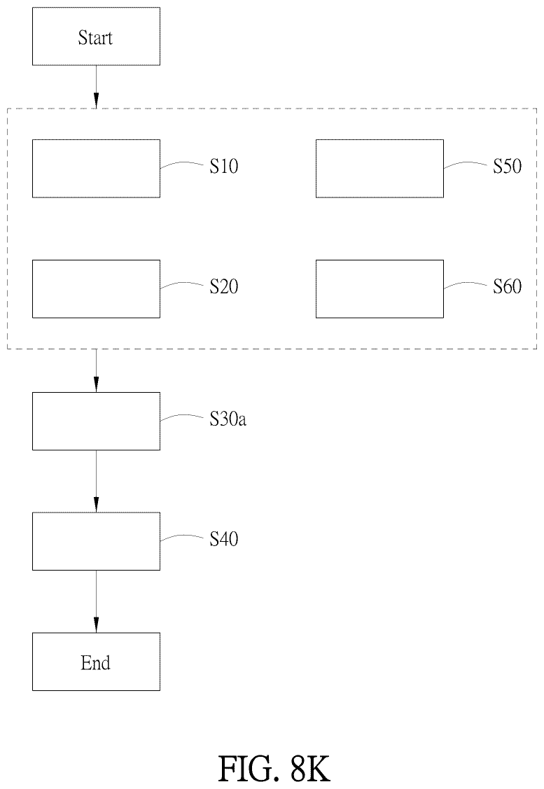

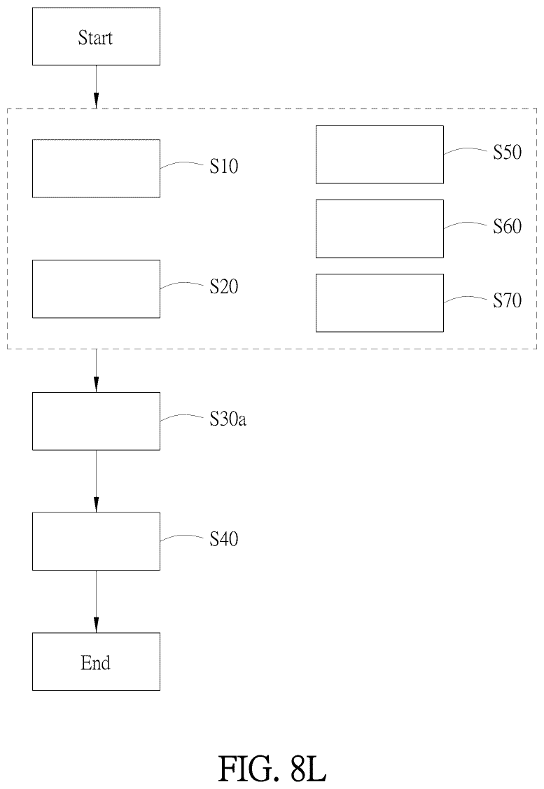

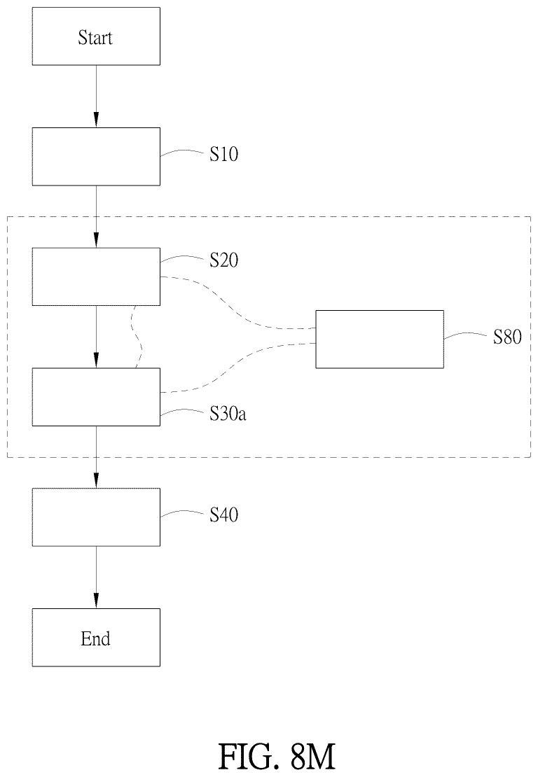

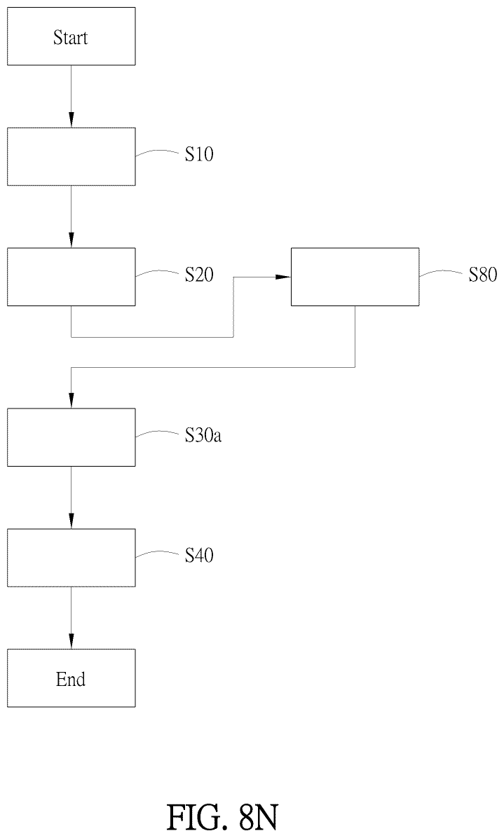

FIGS. 1A to 1B and FIGS. 2A to 2C are schematic diagrams showing a display device according to an embodiment of this disclosure, FIGS. 1C, 1D and 2D are sectional views of the display devices according to different embodiments of this disclosure, FIGS. 3A to 3F, FIGS. 4A to 4F, FIGS. 5A to 5G, and FIGS. 6A to 6B are schematic diagrams showing the display devices according to different embodiments of this disclosure, FIGS. 7A to 7F are schematic diagrams showing the manufacturing procedure of a display device according to an embodiment of this disclosure, and FIGS. 8A to 8N are flowcharts of manufacturing methods of the display device according to different embodiments of this disclosure. To be noted, FIG. 1B is a sectional view of the region 1B in FIG. 1A along the vertical direction Z of the display layer, FIG. 2B is a sectional view of the region 2B in FIG. 2A along the vertical direction Z of the display layer, FIG. 2C is a partially enlarged view of FIG. 2B, and FIG. 3B is a sectional view of the region 3B in FIG. 3A along the vertical direction Z of the display layer.

Referring to FIGS. 1A to 1B and FIGS. 2A to 2C, a display device 100 according to a first embodiment of this disclosure is shown. The display device 100 includes a display layer 10, a textured layer 20 stacked above the display layer 10, and a plurality of light-guide passage units PU30 penetrating through at least the textured layer 20.

The display layer 10 includes a plurality of pixel units PU10. Each pixel unit PU10 includes one or more pixels P10, and each pixel P10 includes one light-emitting element 12 or multiple light-emitting elements 12 (for example, a red light-emitting element 121, a green light-emitting element 122, and a blue light-emitting element 123). The one or more light-emitting elements 12 may be chips or packages, and may be micro LEDs or mini LEDs. The display layer 10 includes a substrate 11, which may have a single layer, multiple layers, or a composite layer, and the pixel units PU10 are arranged on the substrate 11. The display layer 10 may further include an encapsulation material 13 arranged on the substrate 11. In some embodiments, the encapsulation material 13 may be layer-shaped or dot-shaped. In this embodiment, the encapsulation material 13 is layer-shaped. The substrate 11 may further include one or more circuit layers. In some embodiments, the circuit layer may be a passive or active circuitry. To be noted, whether the circuit layer is a passive or active circuitry does not affect its subsequent combination with other electronic components.

The textured layer 20 defines a first surface S21 and a second surface S22 opposite to each other, and the second surface S22 connects to the display layer 10 correspondingly. The textured layer 20 includes a leather texture, a wood texture, or a fabric texture, or a combination including any thereof, but this disclosure is not limited thereto. In this embodiment, the textured layer 20 connects to the display layer 10 through an adhesive layer structure 40.

Each light-guide passage unit PU30 includes one or more light-guide passage structures 30, wherein the light-guide passage units PU30 respectively correspond to the pixel units PU10. Each light-guide passage structure 30 defines a passage 31 at least communicating between the first surface S21 and the second surface S22 of the textured layer 20, and a light-guide material 32 is arranged in the passage 31. The light-guide passage structures 30 in each light-guide passage unit PU30 are free of interference with one another. In some embodiments, the passages 31 may be formed by, for example but not limited to, laser processing or mechanical drilling processes. In this embodiment, the passage 31 may communicate with the adhesive layer 40. In some embodiments, one or ones of the light-guide materials 32 fill corresponding ones of the passages 31. In some embodiments, a refractive index of the light-guide material 32 is greater than a refractive index of the textured layer 20. One or ones of the light-guide passage structures 30 of each light-guide passage unit PU30 are arranged in a vertical direction Z perpendicular to the display layer 10, aligned with one or ones of the pixels P10 of each pixel unit PU10. In addition, the one or ones of the light-guide materials 32 define an optical diffusion surface S32 corresponding to the first surface S21, wherein the optical diffusion surface S32 is, for example but not limited to, roughened.

FIG. 1A and FIG. 1B show an implementation wherein when the one or more light-emitting elements 12 are not illuminated, a display area A10 is integrated with the textured layer 20. In addition, FIG. 2A, FIG. 2B, and FIG. 2C show that when the one or more light-emitting elements 12 are illuminated, at least a portion of light emitted from the one or more light-emitting elements 12 is coupled to corresponding light-guide passage units PU30, through the light-guide material 32, and emitted from the first surface S21 of the textured layer 20. Thus, display information can be seen in the display area A10 on the first surface S21 of the textured layer 20.

Referring to FIG. 2C, in some embodiments, one or ones of the light-guide passage structures 30 of each light-guide passage unit PU30 define an opening O31 at an outward end and an opening O32 at an end facing the display layer 10, wherein a measured area PA31 of the opening O32 projected in the vertical direction Z is not smaller than a pixel area PA12 of a corresponding one of the pixels P10. In some embodiments, the measured area PA31 of the opening O32 projected in the vertical direction Z fully covers the pixel area PA12 of the corresponding one of the pixels P10.

In the display area A10 on the first surface S21 of the textured layer 20, a ratio of a total opening area of the light-guide passage units PU30 is less than 20% of a total area of the display area A10. That is, relative to a total area of the display area A10, a ratio of the total opening area of the openings O31 of one or ones of the light-guide passage structures 30 of each light-guide passage unit PU30 is less than 20% of a total area of the display area A10.

The textured layer 20 may be opaque or slightly transparent. In this case, under a condition where a light wavelength is not less than 380 nanometers and not greater than 780 nanometers, the transmittance of the slightly transparent textured layer is below 5%.

In FIG. 1A and FIG. 1B, the passages 31 penetrate through the textured layer 20 and the adhesive layer structure 40, along at least portions of the passages 31, where the adhesive layer structure 40 and the textured layer 20 conjunct presents a smooth transition at a conjunction portion C40. Unlike the display device 100 in FIG. 1B, in the display device 100′ as shown in FIG. 1C, an adhesive overflow structure 40X extends into the passage 31 around the conjunction portion C40. In some embodiments, a refractive index of the light-guide material 32 is greater than a refractive index of the adhesive layer structure 40.

In addition, in the display device 100c of FIG. 2D, a first opening O31c of the passage 31 at the first surface S21 is larger than a second opening O32c at the second surface S22. In this embodiment, a measured area PA31c of the second opening O32c facing the display layer 10 projected in the vertical direction Z fully covers a pixel area PA12 of a corresponding one of the pixels P10. In this embodiment, the measured area PA31c of the second opening O32c facing the display layer 10 projected in the vertical direction Z is not smaller than the pixel area PA12 of the corresponding one of the pixels P10.

In the display devices 100 and 100′ of FIGS. 1A to 1C and FIGS. 2A to 2C, each light-guide passage unit PU30 has a single light-guide passage structure 30, and each pixel unit PU10 has a single pixel P10, wherein each pixel P10 includes multiple light-emitting elements 121~123. In addition, a light-guide passage pitch S30 is defined between adjacent two light-guide passage units PU30, wherein the light-guide passage pitch S30 is a distance from the light-guide passage structure 30 of one of the light-guide passage units PU30 to the light-guide passage structure 30 of another one of the light-guide passage units PU30. It is worth noting that at least portions of the light-guide passage pitches S30 are equal. For example, all of the light-guide passage pitches S30 are equal-pitched, or portions of the light-guide passage pitches S30 are unequal-pitched. As shown in the display device 100″ of FIG. 1D, portions of the light-guide passage pitches S30 and S30′ are not equal-pitched. The unequal-pitched light-guide passage pitches S30 and S30′ may be applied to curved display devices.

Referring to FIG. 3A and FIG. 3B, in the display device 100A, each light-guide passage unit PU30 has multiple light-guide passage structures 30 and 30′, and each pixel unit PU10 has multiple pixels P10. As shown in FIG. 3B, a first light-guide passage pitch S30A1 is defined between adjacent two light-guide passage units arranged in the vertical direction Z, wherein at least portions of the first light-guide passage pitches S30A1 are equal. That is, at least portions of the first light-guide passage pitches S30A1 may be unequal. One of the light-guide passage structures 30′ of one of the light-guide passage units PU30 is arranged in an oblique direction D1, wherein an angle δ is defined between the oblique direction D1 and the vertical direction Z and is not greater than 90 degrees. Different angles of passage directions of the light-guide passage structures may be applied to curved display devices, and may also be applied for different users to view as shown in FIG. 3D. In addition, a second light-guide passage pitch S30A2 is defined between adjacent two light-guide passage units arranged in the oblique direction D1, wherein at least portions of the second light-guide passage pitches S30A2 are equal. That is, at least portions of the second light-guide passage pitches S30A2 may be unequal.

As shown in FIG. 3E and FIG. 3F, in the 3D structure of the display device 100B, in each pixel unit PU10, one of the pixels P10′(12′) aligned with the light-guide passage structure in the oblique direction D1 and one of the pixels P10(12) aligned with the light-guide passage structure in the vertical direction Z are arranged in a staggered configuration in a planar direction of the display layer. The pixels P10(12) of the pixel units PU10 may be designed to be collinear, and the pixels P10′(12′) of the pixel units PU10 may be designed to be collinear. In some embodiments, the pixels P10′(12′) in the pixel units PU10 are backup pixels for the pixels P10(12) and are substantially identical to the pixels P10(12). The light-guide passage structures 30 and 30′ in each light-guide passage unit PU30 are free of interference with one another. It is worth noting that a light-guide passage unit may include multiple oblique directions aligned with multiple pixels in the pixel unit. It should be noted that the light-guide passage pitch is defined as viewed and defined from the first surface of the textured layer 20. In the drawings of this application, the markings are shown below the display layer 10 for easier identification.

In addition, referring to the display device 100A′ as shown in FIG. 3C, one of the light-guide passage structures 30″ in one of the light-guide passage units PU30 is arranged in an oblique direction D2, where an angle δ′ is defined between the oblique direction D2 and the vertical direction Z and is not greater than 90 degrees, and the oblique direction D2 is not parallel to the oblique direction D1. A second light-guide passage pitch S30A2′ is defined between adjacent two light-guide passage units arranged in the oblique direction D2. FIG. 3C shows that at least portions of these second light-guide passage pitches S30A2 and S30A2′ are unequal. It should be noted that the changes in pixel pitch and light-guide passage pitch are independent of each other. In this embodiment, the pixel pitch shown does not change with changes in the light-guide passage pitch.

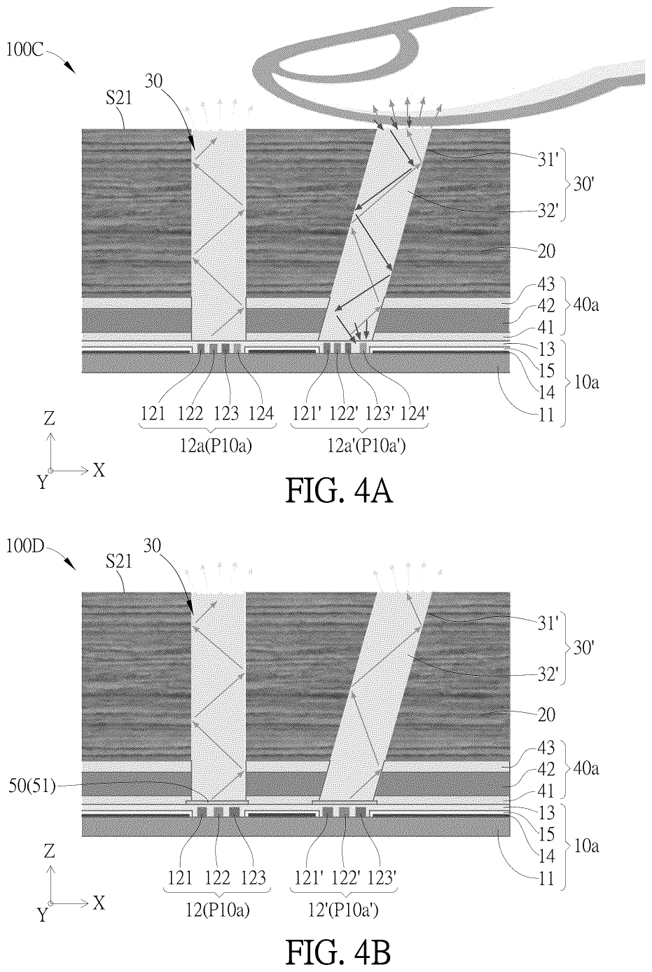

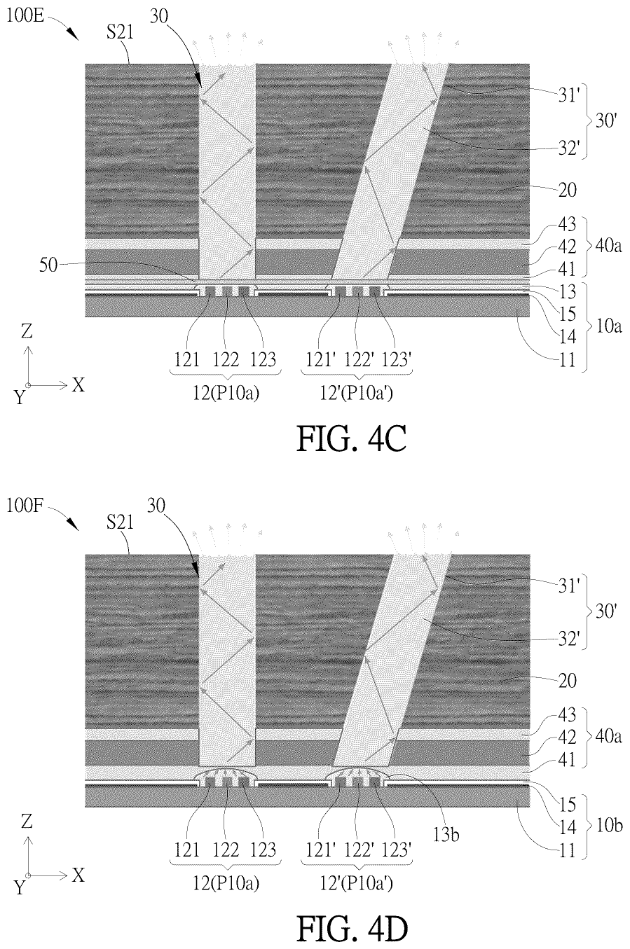

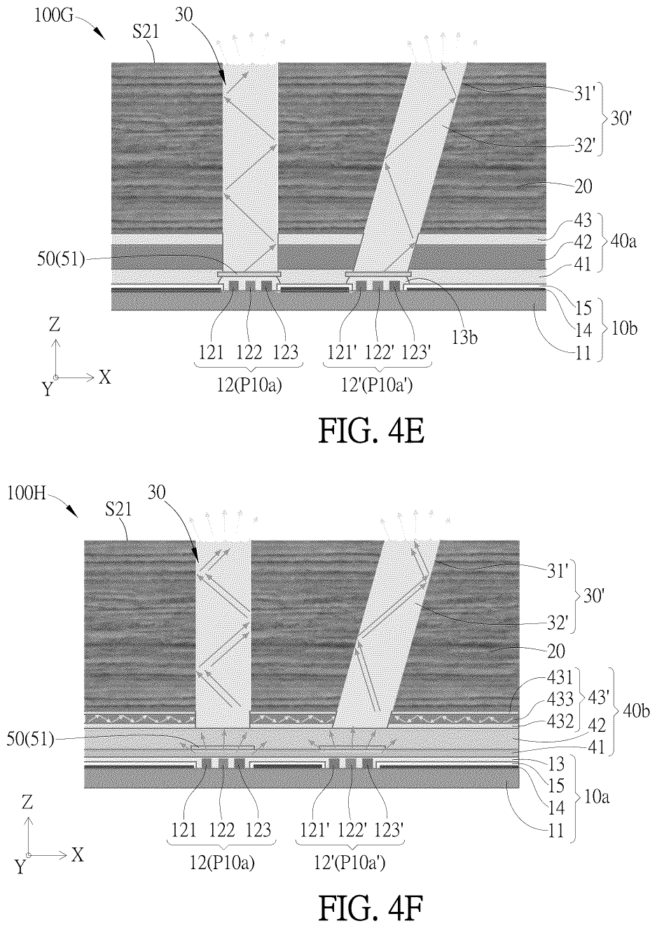

Referring to FIG. 4A, in the display device 100C, one or ones of the pixel units P10a and P10a′ further include a light sensor 124, 124′. The display device 100C further discloses a multilayer adhesive layer structure 40a including a first adhesive layer 41, a second adhesive layer 42, and a third adhesive layer 43. The display device 100C further discloses that the display layer 10a includes a light absorption layer 14 above the substrate 11. The display layer 10a may further include a protection layer 15 disposed on the light absorption layer 14. In this embodiment, the light absorption layer 14 and the protection layer 15 are located between the substrate 11 and the encapsulation material 13, but this disclosure is not limited thereto. In other embodiments, the light absorption layer 14 may be arranged outside the encapsulation material 13.

Referring to FIG. 4B, the display device 100D further discloses a light-transmitting layer 50 arranged between the display layer 10a and the textured layer 20, wherein the light-transmitting layer 50 is away from the first surface S21 of the textured layer 20. The light-transmitting layer 50 includes silicon dioxide or silicon nitride. In this embodiment, the light-transmitting layer 50 is adjacent to the one or more light-emitting elements. The light-transmitting layer 50 may present a continuous surface (as shown in the display device 100E of FIG. 4C), or include a plurality of light-transmitting units 51 respectively corresponding to the pixel units or pixels (as shown in the display device 100D of FIG. 4B). In the display device 100D of this embodiment, the light-transmitting units 51 respectively correspond to the pixels P10a and P10a′. The light-transmitting layer 50 further defines a non-light-transmitting region outside the light-transmitting units 51. The light-transmitting layer 50 has a thickness not greater than 5 μm. In one embodiment, the light-transmitting layer 50 has a thickness not greater than 1 μm.

Referring to FIG. 4D, the display device 100F discloses a plurality of encapsulation materials 13b disposed above the pixels P10a and P10a′ and respectively corresponding to the pixels P10a and P10a′. These encapsulation materials 13b may serve as light-concentrating elements, with the light-concentrating elements being considered as integrated into the display layer 10b. Additionally, the light-concentrating elements may be independent components added to the original display layer structure.

Referring to FIG. 4E, in the display device 100G, the light-transmitting layer 50(51) and the encapsulation material (light-concentrating element) 13b are integrated.

Referring to FIG. 4F, the display device 100H discloses that as the adhesive layer structure 40b includes multiple adhesive layers, and a first refractive index of one adhesive layer 431 and a second refractive index of another adhesive layer 432 are smaller than a third refractive index of an adhesive layer 433 sandwiched between them, wherein the adhesive layer 431 having the first refractive index is adjacent to the textured layer 20, and the adhesive layer 432 having the second refractive index faces toward the display layer 10b. Furthermore, the adhesive layer structure 40b of the display device 100H may retain the original adhesive layers 41 and 42. The display device 100H also discloses that the light-transmitting layer 50(51) may be arranged on one of the adhesive layers (for example, the adhesive layer 41).

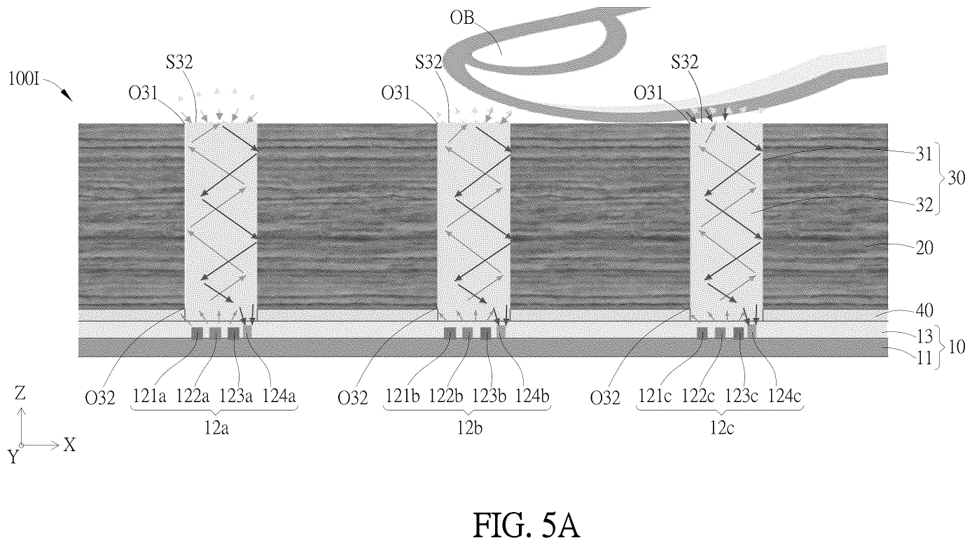

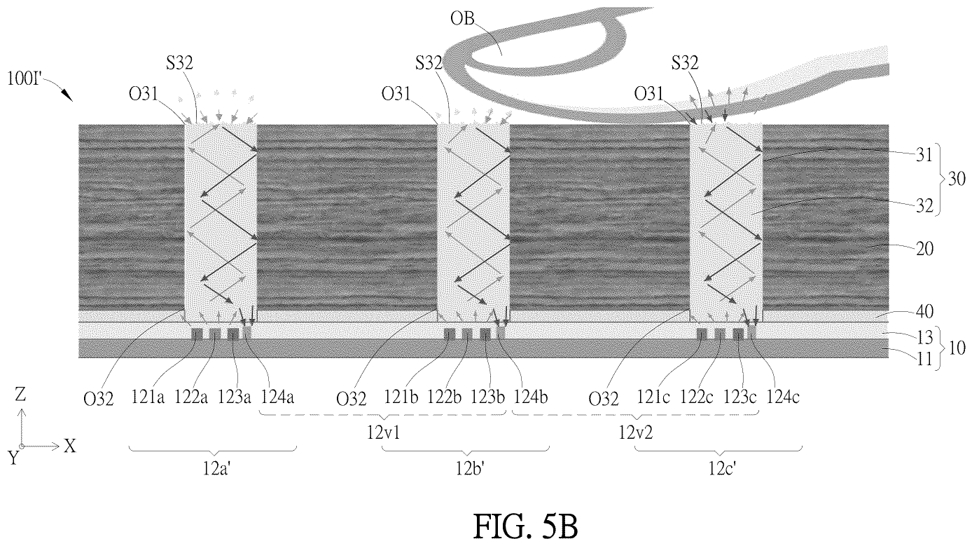

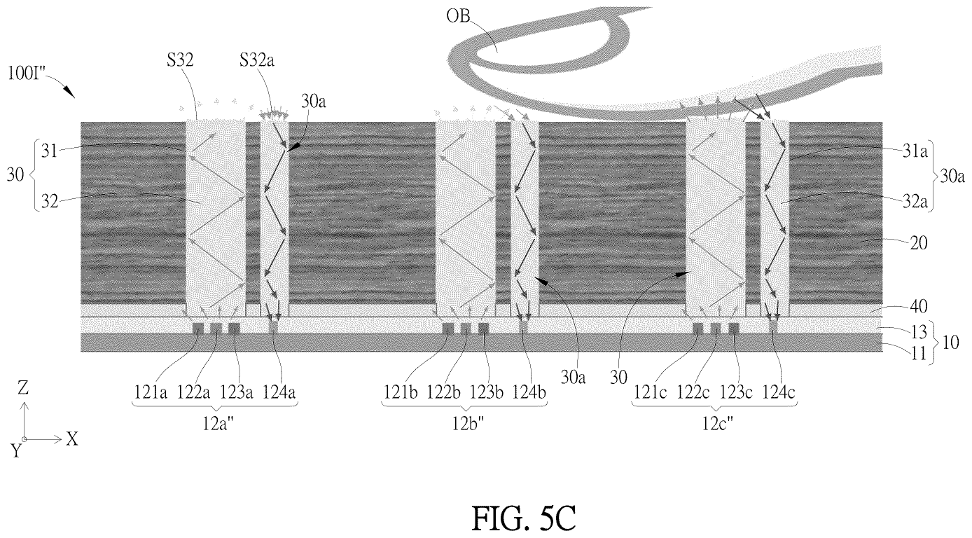

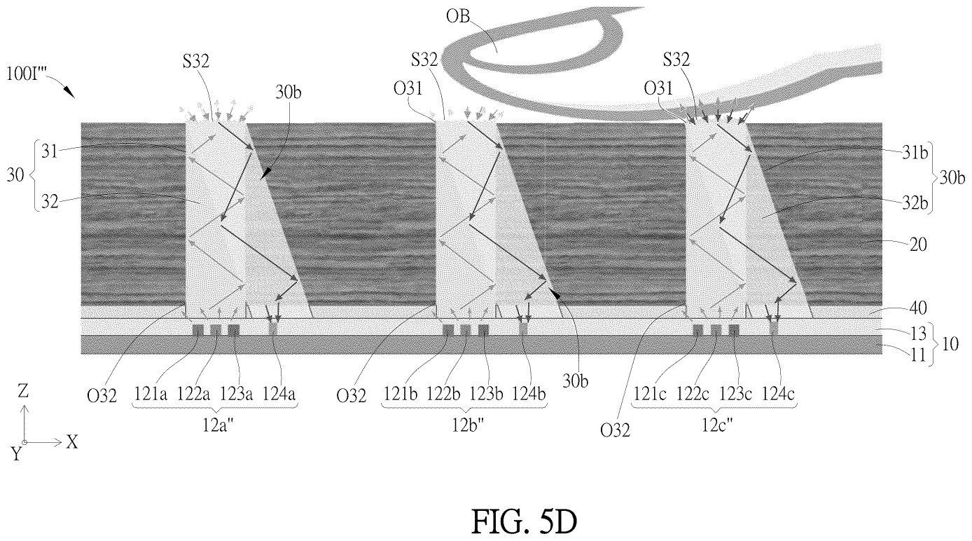

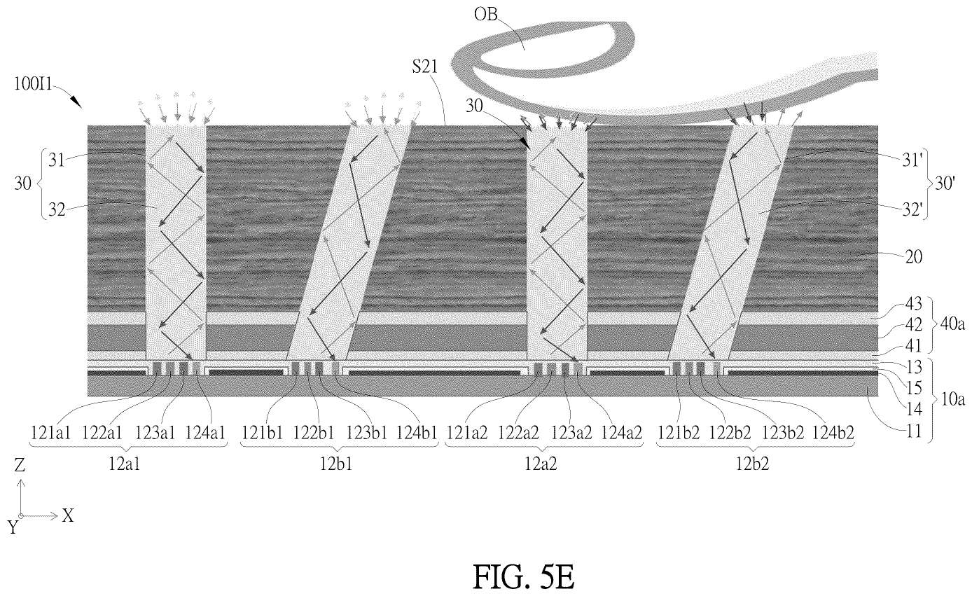

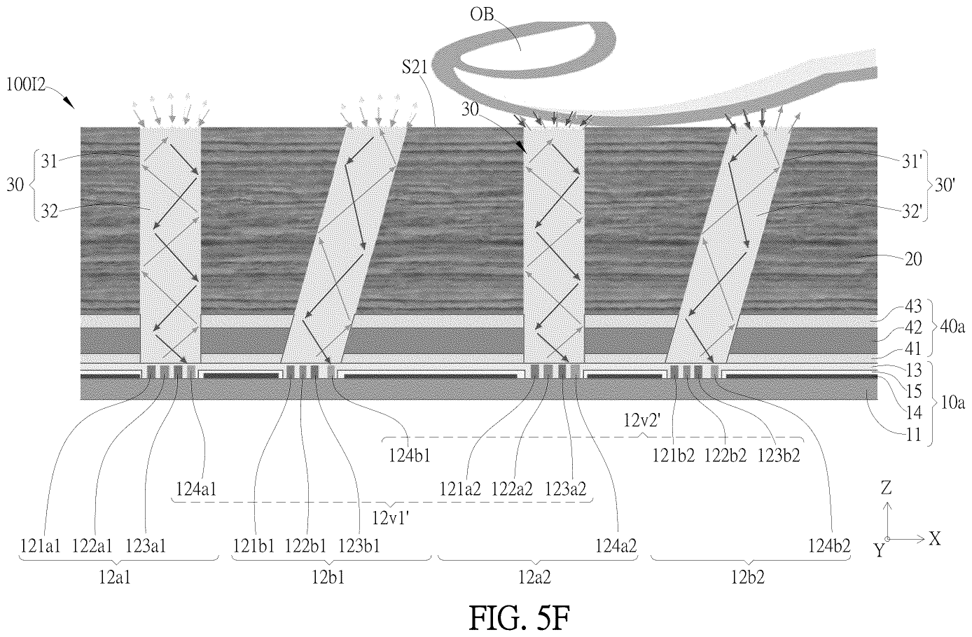

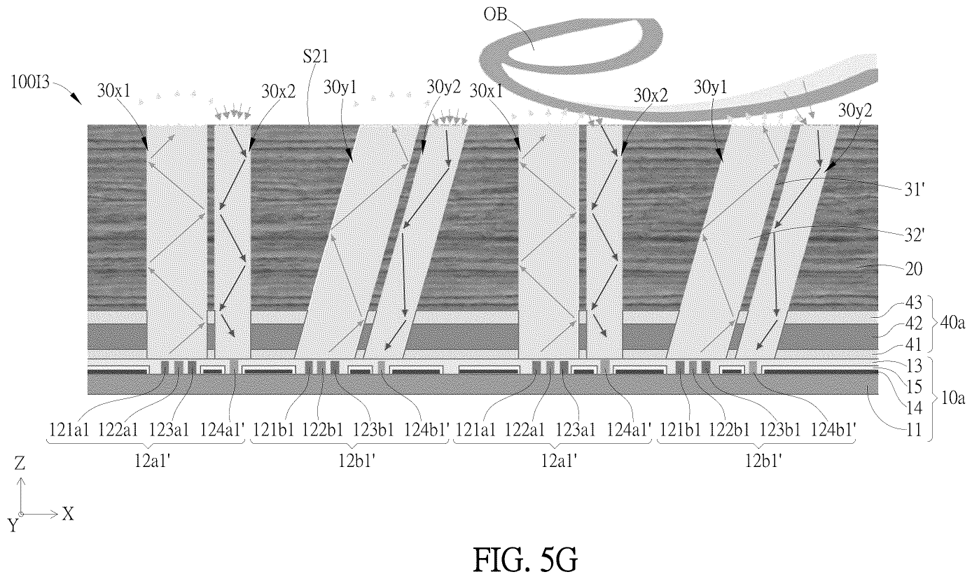

Referring to FIGS. 5A to 5G, which illustrate different embodiments of the display device incorporating light sensors. In a display device 100I shown in FIG. 5A, the light-guide passage structures 30 aligned with one pixel unit 12a, 12b and 12c respectively. The pixel unit 12a includes a Red light-emitting element 121a, a Green light-emitting element 122a, a Blue light-emitting element 123a, and a light sensor 124a. Similarly, the pixel unit 12b includes light-emitting elements 121b, 122b, 123b, and a light sensor 124b, and the pixel unit 12c includes light-emitting elements 121c, 122c, 123c, and a light sensor 124c. In this embodiment, within the same pixel unit, the light sensor and the light-emitting elements share the same light-guide passage structure 30 for detecting a reflected light reflected from an object OB. It is worth noting that this reflected light may be formed either by light emitted from the first surface S21 of the textured layer 20 and reflected by the object OB, or by ambient light reflected by the object OB.

The structural configuration of a display device 100I′ shown in FIG. 5B is similar to that of the display device 100I shown in FIG. 5A, with the distinction that the light sensor 124a in the pixel unit 12a′ is electrically configured to correspond with the light-emitting elements 121b to 123b in the pixel unit 12b′. Between these two pixel units, the emitted light from the light-emitting elements of one pixel unit, after reflection, forms at least part of the reflected light transmitted to the light sensor of another pixel unit. In other words, between the pixel units 12a′ and 12b′, the light emission timing of the light-emitting elements 121b to 123b of the pixel unit 12b′ at least partially overlaps with the detection timing of the light sensor 124a of the pixel unit 12a′, enabling the light sensor 124a of the pixel unit 12a′ to detect the reflected light from the light-emitting elements 121b to 123b of the pixel unit 12b′. In addition, between these two of the pixel units, the emitted light from the light-emitting elements 121b to 123b of the pixel unit 12b′, after reflection, forms at least part of the reflected light transmitted to the light sensor 124a of the pixel unit 12a′. The two of the pixel units may be adjacent or positioned as close as possible to each other. Furthermore, between the pixel units 12a′ and 12b′, the light emission timing of the light-emitting elements 121b to 123b of the pixel unit 12b′ is offset from the light emission timing of the light-emitting elements 121a to 123a of the pixel unit 12a′, ensuring that the light-emitting elements 121a to 123a of the pixel unit 12a′ do not interfere with the light sensor 124a of the pixel unit 12a′ in detecting the reflected light from the light-emitting elements 121b to 123b of the pixel unit 12b′. It can be understood that between the pixel units 12a′ and 12b′, the light-emitting elements 121b to 123b of the pixel unit 12b′, being electrically corresponding to the light sensor 124a of the pixel unit 12a′, may be viewed as a virtual pixel unit 12v1, and similarly for a virtual pixel unit 12v2 and so forth. However, the explanation of virtual pixel units is solely for understanding the cross-pixel-unit light detection and is not intended as a necessary limitation.

In the display device 100I″ shown in FIG. 5C, each light-guide passage unit contains a light-guide passage structure 30 and an auxiliary light-guide passage structure 30a, wherein one light-guide passage structure 30 is aligned with the light-emitting elements 121a to 123a of the pixel unit 12a″, and the corresponding auxiliary light-guide passage structure 30a is aligned with the light sensor 124a of the same pixel unit 12a″; another light-guide passage structure 30 is aligned with the light-emitting elements 121b to 123b of the pixel unit 12b″, and the corresponding auxiliary light-guide passage structure 30a is aligned with the light sensor 124b of the same pixel unit 12b″; and another light-guide passage structure 30 is aligned with the light-emitting elements 121c to 123c of the pixel unit 12c″, and the corresponding auxiliary light-guide passage structure 30a is aligned with the light sensor 124c of the same pixel unit 12c″. In this embodiment, the passage of the auxiliary light-guide passage structure 30a does not interfere with the passage of the light-guide passage structure 30. That is, the auxiliary light-guide passage structure 30a and the light-guide passage structure 30 are independent of each other. In addition, the auxiliary light-guide passage structure 30a and the light-guide passage structure 30 may be positioned as close as possible to each other.

In reference to FIG. 5D, each light-guide passage unit contains a light-guide passage structure 30 and an auxiliary light-guide passage structure 30b, wherein one light-guide passage structure 30 is aligned with the light-emitting elements 121a to 123a of the pixel unit 12a″, and the corresponding auxiliary light-guide passage structure 30b is aligned with the light sensor 124a of the same pixel unit 12a″; another light-guide passage structure 30 is aligned with the light-emitting elements 121b to 123b of the pixel unit 12b″, and the corresponding auxiliary light-guide passage structure 30b is aligned with the light sensor 124b of the same pixel unit 12b″; and another light-guide passage structure 30 is aligned with the light-emitting elements 121c to 123c of the pixel unit 12c″, and the corresponding auxiliary light-guide passage structure 30b is aligned with the light sensor 124c of the same pixel unit 12c″. In this embodiment, the passage of the auxiliary light-guide passage structure 30b partially interferes with the passage of the light-guide passage structure 30. That is, corresponding to the first surface S21, an optical diffusion surface S32 of the light-guide passage structure 30 and an optical diffusion surface of the auxiliary light-guide passage structure 30b are at least partially overlapped. In this embodiment, the light-guide passage structure 30 and the auxiliary light-guide passage structure 30b share the same optical diffusion surface S32 as an example.

The display device 100I1 shown in FIG. 5E further incorporates inclined light-guide passage structures 30′ in an oblique direction based on FIG. 5A. The light-guide passage structures 30 are aligned with the pixel units 12a1 and 12a2 respectively. The pixel unit 12a1 includes a Red light-emitting element 121a1, a Green light-emitting element 122a1, a Blue light-emitting element 123a1, and a light sensor 124a1, and so forth. The inclined light-guide passage structures 30′ are aligned with the pixel units 12b1 and 12b2 respectively. The pixel unit 12b1 includes a Red light-emitting element 121b1, a Green light-emitting element 122b1, a Blue light-emitting element 123b1, and a light sensor 124b1, and so forth.

The structural configuration of the display device 100I2 shown in FIG. 5F is similar to that of the display device 100I1 in FIG. 5E, with the distinction that the light sensor 124a1 in the vertically-aligned pixel unit 12a1 is electrically configured to correspond with the light-emitting elements 121a2 to 123a2 in the vertically-aligned pixel unit 12a2; while the light sensor 124b1 in an inclined-aligned pixel unit 12b1 is electrically configured to correspond with the light-emitting elements 121b2 to 123b2 in the inclined-aligned pixel unit 12b2. Similar to FIG. 5B, the virtual pixel units 12v1′ and 12v2′ can be defined in the display device 100I2. It is to be understood that FIG. 5F represents merely one exemplary embodiment, where the light sensors in the vertically-aligned direction are configured to correspond to light-emitting elements in the vertically-aligned direction. Without limiting the scope of this disclosure, the correspondence between light sensors and light-emitting elements may be implemented in various configurations, including for example but not limited to: light sensors in the vertically-aligned direction corresponding to light-emitting elements in the inclined-aligned direction, or light sensors in the inclined-aligned direction corresponding to light-emitting elements in the vertically-aligned direction.

The display device 100I3 shown in FIG. 5G further incorporates auxiliary light-guide passage structures based on FIG. 5E. In the vertical direction, the light-guide passage unit 30x contains a light-guide passage structure 30x1 and an auxiliary light-guide passage structure 30x2, wherein the light-guide passage structure 30x1 is aligned with the light-emitting elements 121a1 to 123a1 of the pixel unit 12a1′, and the auxiliary light-guide passage structure 30x2 is aligned with the light sensor 124a1′ of the same pixel unit 12a1′. In an oblique direction, the light-guide passage unit 30y contains a light-guide passage structure 30y1 and an auxiliary light-guide passage structure 30y2, wherein the light-guide passage structure 30y1 in the oblique direction is aligned with the light-emitting elements 121b1 to 123b1 of the pixel unit 12b1′, and the auxiliary light-guide passage structure 30y2 in an oblique direction is aligned with the light sensor 124b1′ of the same pixel unit 12b1′. In this embodiment, the passages of the auxiliary light-guide passage structures do not interfere with the passages of the light-guide passage structures. That is, the auxiliary light-guide passage structure 30x2 (30y2) and the light-guide passage structure 30x1 (30y1) are independent of each other.

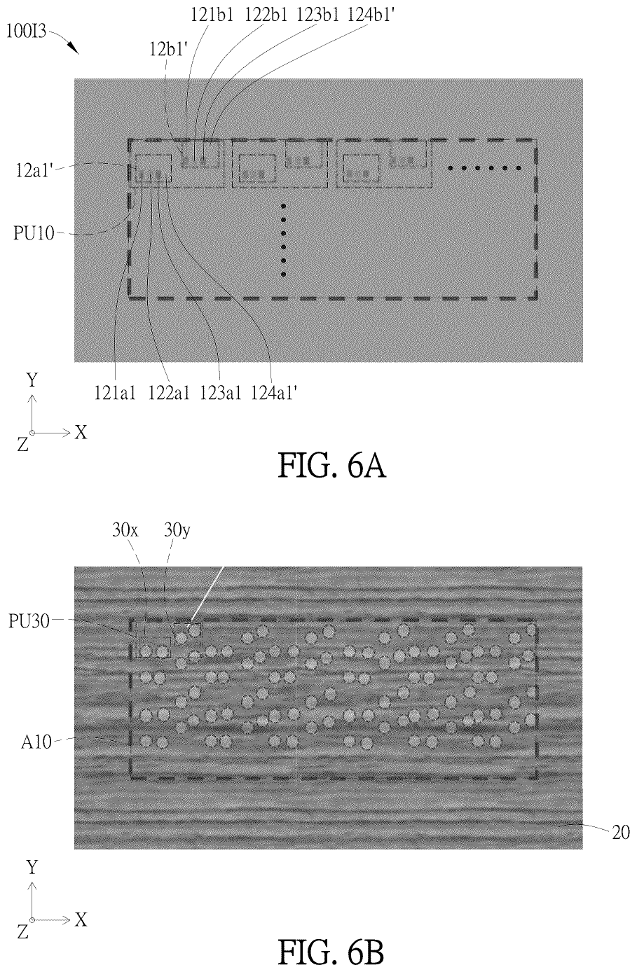

Referring to the display device 100I3 in FIG. 6A, within each pixel unit PU10, one pixel 12b1′ aligned with the light-guide passage structure in the oblique direction D1 and one pixel 12a1′ aligned with the light-guide passage structure in the vertical direction Z are arranged in a staggered configuration along the planar direction of the display layer. In some embodiments, among these pixel units PU10, the pixel 12b1′ serves as a backup pixel for the pixel 12a1′ and is substantially identical to the pixel 12a1′. In some embodiments, within these pixel units PU10, the light-emitting elements 122a1 to 123a1 and light sensor 124a1′ in the pixel 12a1′ and the light-emitting elements 122b1 to 123b1 and light sensor 124b1′ in the pixel 12b1′ may also be arranged in a staggered configuration. This is illustrated here only by the staggered arrangement of the light-emitting elements 122b1 to 123b1 and light sensor 124b1′ in the pixel 12b1′. As shown in FIG. 6B, in the display device 100I3, each light-guide passage unit PU30 (30x, 30y) corresponds respectively to the pixel units 12a1′ and 12b1′. The display device 100I3 contains multiple light-guide passage structures 30x1 (30y1) and auxiliary light-guide passage structures 30x2 (30y2).

Referring to the flowchart of FIG. 8A, a manufacturing method of the display device 100 includes the steps of: preparing a display layer (step S10), stacking a textured layer above the display layer, wherein the textured layer is formed by printing (step S20), laser-forming a plurality of passages through the textured layer 20 in a specific direction by implementing laser LA (step S30a), and arranging light-guide materials in the passages (step S40). The flowchart of FIG. 8A may be further expanded according to other requirements.

Referring to FIG. 7A to FIG. 7F, along with the flowchart of FIG. 8B, showing the steps of one manufacturing method of the display device 100A, which may be viewed in conjunction with the aforementioned paragraphs and related drawings and reference numerals. FIG. 7A discloses: preparing a display layer 10 in step S10 and stacking a textured layer 20 above the display layer 10 in step S20. FIG. 7B discloses: implementing laser LA toward the textured layer 20 in a vertical direction Z to form a first group of multiple passages 31 in step S31. FIG. 7C discloses implementing laser LA toward the textured layer 20 in an oblique direction D1 to form a second group of multiple passages 31′ in step S32. FIG. 7D discloses using an apparatus AD to arrange the light-guide material 32 in the first group of passages 31 in step S41, and FIG. 7E discloses using the same apparatus AD or another apparatus AD to arrange the light-guide material 32′ in the second group of passages 31′ in step S42, thereby completing the display device 100A. The apparatus AD can output the required light-guide material through processes such as coating, scraping, or inkjet steps. It should be noted that the step S41 can be omitted (not shown in the figure), with step S42 handling both the first and second groups of passages 31 and 31′ together. That is, the processes shown in FIG. 7D and FIG. 7E may be integrated into a single step, wherein the light-guide materials in passages of different angles may be either the same or different materials. It is worth noting that the steps S30a and S40 may be expanded into sub-steps according to the number of light-guide passage units and pixel units. Similarly, the light-guide materials 31 and 32 can be the same or different materials. The flowchart of FIG. 8C discloses another implementation of process sequence, namely an alternating form of the steps S31, S41, S32 and S42.

The flowchart of FIG. 8D includes a step S50 between the steps S10 and S20, for arranging an adhesive layer structure between the display layer and the textured layer to bond the display layer and the textured layer. In the step S50, the adhesive layer structure may be constituted by a single adhesive layer or multiple adhesive layers, and thus can be further divided into multiple sub-steps. Furthermore, the adhesive layer structure may be pre-attached to the display layer and/or the textured layer for facilitating bonding with another layer. Alternatively, the adhesive layer structure may be arranged layer by layer (if needed) on the display layer through processes such as coating. The adhesive layer structure and its adhesive layers also need to consider matching refractive indices with the textured layer and the light-guide material, which, in addition to providing adhesion effects, can further provide a high-efficiency light-guide system, as can be known from the aforementioned multiple embodiments. For example, but not limited thereto, a first refractive index of one of two adhesive layers and a second refractive index of another one of the two adhesive layers are smaller than a third refractive index of an adhesive layer sandwiched between the two adhesive layers, and one of the adhesive layers having the first refractive index is adjacent to the textured layer.

The flowchart of FIG. 8E includes a step S60, which can be implemented in combination with the steps S10 and S20, for arranging a light-transmitting layer between the display layer and the textured layer. In the step S60, the light-transmitting layer includes silicon dioxide or silicon nitride material and can serve as a stop point for laser implementation to avoid damaging the light-emitting elements. Therefore, the arrangement of the light-transmitting layer only needs to satisfy the aforementioned purpose and is not limited to being necessarily adjacent to the light-emitting elements. Furthermore, to satisfy the aforementioned purpose, it can be reasonably inferred that the portions of the light-transmitting layer corresponding to the light-emitting elements should completely cover the light-emitting elements. In addition, the light-transmitting layer may be integrated into the display panel or be independent from the display panel (as in step S60′ of FIG. 8F), the light-transmitting layer may be a continuous layer, or may form secondary light-transmitting units above the light-emitting elements, or may be formed into multiple light-transmitting units with non-light-transmitting regions connecting these light-transmitting units through patterning of a continuous layer material. The flowcharts in this application should not have limitations on this.

The flowchart of FIG. 8G includes a step S70, which can be implemented in combination with the steps S10 and S20, for arranging light-concentrating elements between the display layer and the textured layer. In the step S70, the light-concentrating elements may be part of the encapsulation material or independently arranged components, which can provide light-concentrating functionality for the light-emitting elements to improve overall light emission efficiency. Therefore, the arrangement of the light-concentrating elements only needs to satisfy the aforementioned purpose and is not limited to being necessarily adjacent to the light-emitting elements. Furthermore, to satisfy the aforementioned purpose, it can be reasonably inferred that the portions of the light-concentrating elements corresponding to the light-emitting elements should completely cover the light-emitting elements. The arrangement of light-concentrating elements can be reasonably inferred to be implemented before the adhesive layer structure implementation step S30a (as in step S70′ of FIG. 8H) or between the implementation steps of the adhesive layer structure. The flowcharts mentioned in this application should not have limitations on this.

Referring to the flowcharts of FIGS. 8I to 8L, the steps S10 and S20 can be further combined with the steps S50, S60, S70 and other arrangements. Any arrangements that do not conflict with step S30a should be within the equivalent scope of this application.

For ease of explanation, based on FIG. 8A, taking FIGS. 8M and 8N as examples, in (as in FIG. 8M) or before (as in FIG. 8N) the step S30a, the flowchart further includes a step S80 of lighting up the light-emitting elements as alignment marks for laser implementation to form the passages. In this embodiment, the textured layer has a transmittance below 5% under visible light wavelength conditions (for example, light wavelength not less than 380 nanometers and not greater than 780 nanometers). Accordingly, when the light-emitting elements are lit up, the laser implementation process to form the passages can use the faint light from the light-emitting elements observed on the first surface of the textured layer as alignment marks. It can be understood that the step S80 may also be integrated into FIGS. 8I to 8L.

In summary, the display device of this disclosure includes a display layer, a textured layer, and a plurality of light-guiding passage units. The display layer includes a plurality of pixel units, each pixel unit includes one or more pixels, and each pixel includes one or more light-emitting elements. The textured layer is stacked above the display layer, wherein the textured layer has a first surface and a second surface disposed opposite to each other, and the second surface corresponds to and connects with the display layer. Each light-guiding passage unit includes one or more light-guiding passage structures penetrating through the textured layer. The light-guiding passage units respectively correspond to the pixel units. Each light-guiding passage structure includes a passage communicating between the first and second surfaces of the textured layer, and a light-guide material arranged in the passage. Each light-guiding passage unit's one or ones of the light-guiding passage structures is arranged along a vertical direction perpendicular to the display layer, aligned with one or ones of the pixels of each pixel unit. At least a portion of the light emitted from the light-emitting elements couples with the light-guiding passage units and emits from the first surface of the textured layer. Based on the design of this disclosure, the display device takes into account both the integration of the texture layer and the clarity of the displayed contents.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A display device, comprising:
a display layer comprising a plurality of pixel units, wherein each of the pixel units includes one or more pixels, and each of the pixels includes a plurality of light-emitting elements;
a textured layer stacked above the display layer, wherein the textured layer defines a first surface and a second surface opposite to each other, and the second surface connects to the display layer correspondingly; and
a plurality of light-guide passage units penetrating through at least the textured layer, wherein each of the light-guide passage units includes one or more light-guide passage structures, the light-guide passage units respectively correspond to the pixel units, each of the light-guide passage structures defines a passage at least communicating between the first surface and the second surface of the textured layer, and a light-guide material is arranged in the passage;
wherein one or ones of the light-guide passage structures of each of the light-guide passage units are arranged in a vertical direction perpendicular to the display layer, and aligned with one or ones of the pixels of each of the pixel units; and
wherein at least a portion of light emitted from at least one of the light-emitting elements is coupled to the light-guide passage units and emitted from the first surface of the textured layer.

2. The display device as claimed in claim 1, wherein the textured layer comprises a leather texture, a wood texture, or a fabric texture, or a combination including any thereof.

3. The display device as claimed in claim 1, wherein the passages are formed by laser processing.

4. The display device as claimed in claim 1, wherein a first opening of one of the passages at the first surface is larger than a second opening thereof at the second surface.

5. The display device as claimed in claim 1, wherein one of the light-guide materials defines an optical diffusion surface corresponding to the first surface.

6. The display device as claimed in claim 1, wherein one of the light-guide materials fills a corresponding one of the passages.

7. The display device as claimed in claim 1, wherein the one or more light-emitting elements is(are) micro LED(s) or mini LED(s).

8. The display device as claimed in claim 1, wherein as each of the light-guide passage units is the single light-guide passage structure and each of the pixel units is the single pixel, a light-guide passage pitch is defined between adjacent two of the light-guide passage units, wherein the light-guide passage pitch is a distance from the light-guide passage structure of one of the adjacent two light-guide passage units to the light-guide passage structure of the other one of the adjacent two light-guide passage units; wherein at least portions of the light-guide passage pitches are equal.

9. The display device as claimed in claim 1, wherein as each of the light-guide passage units has the multiple light-guide passage structures and each of the pixel units has the multiple pixels, at least portions of the light-guide passage structures of each of the light-guide passage units respectively correspond to at least portions of the pixels of each of the pixel units; wherein a light-guide passage pitch is defined between adjacent two of the light-guide passage units, from the light-guide passage structure, which is arranged in the vertical direction perpendicular to the display layer, of one of the adjacent two light-guide passage units to a corresponding one of the light-guide passage structures, which is arranged in the vertical direction perpendicular to the display layer, of the other one of the adjacent two light-guide passage units; wherein at least portions of the light-guide passage pitches are equal.

10. The display device as claimed in claim 1, wherein as each of the light-guide passage units has the multiple light-guide passage structures, and each of the pixel units has the multiple pixels, at least portions of the light-guide passage structures of each of the light-guide passage units respectively correspond to at least portions of the pixels of each of the pixel units; wherein one of the light-guide passage structures of each of the light-guide passage units is arranged in an oblique direction, wherein an angle defined between the oblique direction and the vertical direction is not greater than 90 degrees.

11. The display device as claimed in claim 1, wherein the one or ones of the light-guide passage structures of each of the light-guide passage units define an opening facing the display layer, wherein a measured area of the opening projected on the display layer in the vertical direction is not smaller than a pixel area of a corresponding one of the pixels.

12. The display device as claimed in claim 1, wherein the one or ones of the light-guide passage structures of each of the light-guide passage units define an opening facing the display layer, wherein a measured area of the opening projected on the display layer in the vertical direction fully covers a pixel area of a corresponding one of the pixels.

13. The display device as claimed in claim 1, wherein one or ones of the pixel units include(s) a light sensor, which detects a reflected light reflected from an object and backward to the light sensor.

14. The display device as claimed in claim 1, further comprising an adhesive layer structure; wherein the display layer is connected to the textured layer through the adhesive layer structure.

15. The display device as claimed in claim 1, wherein a refractive index of the light-guide material is greater than a refractive index of the textured layer.

16. The display device as claimed in claim 1, further comprising a light-transmitting layer arranged between the display layer and the textured layer; wherein the light-transmitting layer is disposed away from the first surface of the textured layer.

17. The display device as claimed in claim 1, wherein the textured layer is opaque.

18. The display device as claimed in claim 1, wherein the textured layer defines a transmittance, and under a condition where a light wavelength is not less than 380 nanometers and not greater than 750 nanometers, the transmittance is below 5%.

19. The display device as claimed in claim 1, wherein the light-guide passage units collectively define a total opening area, wherein relative to a display area of the display device, a ratio of the total opening area is less than 20%.

20. The display device as claimed in claim 1, further comprising a plurality of light-concentrating elements disposed above the pixels and respectively corresponding to the pixels.
